(19) United States
(12) Patent Application Publication
(10) Pub. No.: US 2020/0009845 A1
(43) Pub. Date: Jan. 9, 2020

(54) METHOD FOR MANUFACTURING MEMBER TO BE TREATED AND LAMINATE

(71) Applicant: FUJIFILM Corporation, Tokyo (JP)

(72) Inventors: Shotaro OGAWA, Haibara-gun (JP); Kenji ICHIKAWA, Haibara-gun (JP); Koji TONOHARA, Haibara-gun (JP)

(73) Assignee: FUJIFILM Corporation, Tokyo (JP)

(21) Appl. No.: 16/577,002

(22) Filed: Sep. 20, 2019

Related U.S. Application Data
(63) Continuation of application No. PCT/JP2018/017195, filed on Apr. 27, 2018.

(30) Foreign Application Priority Data
May 24, 2017 (JP) 2017-102912

(51) Int. Cl. B32B 37/00; H01L 21/683; H01L 23/00; B24B 37/30

(52) U.S. Cl. CPC B32B 37/025; H01L 21/6835; H01L 24/27; B24B 37/30; H01L 2224/27602; H01L 2224/27003; H01L 2224/275; H01L 2924/40404; H01L 2221/68386

(57) ABSTRACT

A method for manufacturing a member to be treated includes: a first bonding step of bonding a member to be treated containing metal oxide and a first support to each other with a first adhesive layer; a first surface processing step of forming a first processed surface on the member to be treated; a first surface contact step of bringing a support having adhesiveness, an adsorption support which adsorbs the member to be treated, or a second adhesive layer, into contact with the first processed surface; a second bonding step of bonding the member to be treated and a second support with the second adhesive layer; and a second surface processing step of forming a second processed surface on a rear surface of the first processed surface of the member to be treated. In a case where the support having adhesiveness or the adsorption support and the first processed surface are in contact with each other, the support having adhesiveness or the adsorption support is removed in the first surface contact step. A first adhesive layer removing step of removing the first adhesive layer from the member to be treated is included between the first surface contact step and the second surface processing step.

### CROSS-REFERENCE TO RELATED APPLICATIONS

This application is a Continuation of PCT International Application No. PCT/JP2018/017195 filed on Apr. 27, 2018, which claims priority under 35 U.S.C. § 119(a) to Japanese Patent Application No. 2017-102912 filed on May 24, 2017. Each of the above application(s) is hereby expressly incorporated by reference, in its entirety, into the present application.

### BACKGROUND OF THE INVENTION

### 1. Field of the Invention

The present invention relates to a method for manufacturing a member to be treated of performing a treatment such as a smoothing treatment on both surfaces of the member to be treated containing metal oxide, and a laminate used in the method for manufacturing a member to be treated, and particularly, a method for manufacturing a member to be treated treatment such as a smoothing treatment on both surfaces of the member to be treated, even in a case where the member to be treated containing metal oxide is brittle, and a laminate used in the method for manufacturing a member to be treated.

### 2. Description of the Related Art

In related art, the treatment such as the smoothing treatment or the like is performed on both surfaces of a member to be treated such as a substrate. The smoothing treatment performed on both surfaces of the substrate will be described using a substrate.

FIGS. 48 to 54 are schematic views showing a treatment method of a member to be treated of the related art in order of steps. FIGS. 48 to 54 are respectively schematic views showing one step of the treatment method of the member to be treated of the related art.

As shown in FIG. 48, a first support 100 is prepared. A glass substrate or a silicon wafer is used, for example, for the first support 100.

Next, as shown in FIG. 49, a first temporary bonding layer 102 is provided on the first support 100. The first temporary bonding layer 102 is configured with a temporary bonding material or a temporary bonding sheet having adhesive strength which decreases due to exposure or heating.

Next, as shown in FIG. 50, a substrate 104 is bonded to the first temporary bonding layer 102 with a rear surface 104b facing the first temporary bonding layer 102. In this state, the smoothing treatment such as polishing or grinding is performed on a front surface 104a of the substrate 104.

Next, the adhesive strength of the first temporary bonding layer 102 is decreased by exposure or heating, and as shown in FIG. 51, the substrate 104 is peeled off from the first support 100.

Next, as shown in FIG. 52, a second support 106 is prepared. In the same manner as in the first support 100, a glass substrate or a silicon wafer is used, for example, for the second support 106.

Next, as shown in FIG. 53, a second temporary bonding layer 108 is provided on the second support 106. In the same manner as in the first temporary bonding layer 102, the second temporary bonding layer 108 is configured with a temporary bonding material or a temporary bonding sheet having adhesive strength which decreases due to exposure or heating.

Next, as shown in FIG. 54, the substrate 104 is bonded to the second temporary bonding layer 108 with the front surface 104a facing the second temporary bonding layer 108. In this state, the smoothing treatment such as polishing or grinding is performed on the rear surface 104b of the substrate 104. By doing so, the smoothing treatment is performed on both surfaces of the substrate 104.

As a method of performing the smoothing treatment on both surfaces of the substrate or the like, the followings have been proposed, in addition to the method described above.

JP2010-149211A discloses a surface polishing method of a thin film brittle material of polishing one surface of the thin film brittle material having a thickness equal to or smaller than 500 μm and a Young's modulus equal to or greater than 1.0×108 by fixing the other surface, and polishing both surfaces by polishing at least one surface twice or more, by changing the fixed surface and the polished surface with each other, in which ruggedness having a depth or height of 5 to 100 μm and a pitch of 30 to 2000 μm is provided on a surface for fixing that is in contact with the fixed surface of the thin film brittle material. A structure having an anodic oxidation coating as a main body is provided as the thin film brittle material.

JP2010-149211A discloses that the thin film brittle material is fixed to a fixing member with a WAX adhesive (ALCOWAX manufactured by Nikka Seiko Co., Ltd.), a surface opposite to the bonded surface is polished, the polished surface is bonded and fixed to the fixing member with the WAX adhesive, and then, the other surface is polished.

A method for manufacturing a semiconductor device of JP2015-201548A is a manufacturing method including a step of temporarily bonding a first surface of a semiconductor wafer to a first substrate through a first adhesive, a step of temporarily bonding a second surface opposite to the first surface of the semiconductor wafer to a second substrate through a second adhesive, so that a side surface of the first adhesive is exposed and a side surface of the second adhesive is not exposed, and a step of peeling off the first substrate from the semiconductor wafer in a state where the semiconductor wafer is temporarily bonded to the second substrate. JP2015-201548A discloses the manufacturing method further including a step of polishing the second surface in a state where the semiconductor wafer is temporarily bonded to the first substrate.

### SUMMARY OF THE INVENTION

In the smoothing treatment on both surfaces of the substrate of the related art, in a case where the substrate 104 is a thin and brittle material, the risk of a damage such as deformation or break on the substrate 104 increases, in a case where the substrate 104 is peeled off from the first support 100 and the front surface 104a subjected to the smoothing treatment is bonded to the second temporary bonding layer 108, for the transfer of the substrate 104. As the size of the substrate 104 is great, the risk described above increases. Particularly, the risk significantly increases, in a case where the substrate 104 is a material having a low brittleness such as metal oxide. As described above, in a case where deformation or break occurs on the substrate 104, a decrease in stability of production and a decrease in yield rate occurs, and productivity decreases. Accordingly, the production cost increases.

As described above, JP2010-149211A discloses that a thin film brittle material is fixed to a fixing member with a WAX adhesive, a surface opposite to the bonded surface is polished, the polished surface is bonded and fixed to the fixing member with the WAX adhesive, and then, the other surface is polished. In this case, it is necessary to peel off the other unpolished surface and the fixing member from each other, but it is difficult to only peel off the unpolished surface, because both of the polished surface and the other surface are fixed to the same adhesive.

In addition, in JP2015-201548A, a semiconductor is a target, and thus, the method may not work with a brittle material having a lower brittleness than that of the semiconductor.

As described above, currently, the smoothing treatment is not stably performed, in a case of performing the smoothing treatment on both surfaces of a brittle material having a low brittleness.

An object of the invention is to solve the problems regarding the technology of the related art described above and to provide a method for manufacturing a member to be treated having both surfaces, on which a treatment such as a smoothing treatment can be stably performed, even in a case where the member to be treated containing metal oxide is brittle, and a laminate.

In order to achieve the object described above, there is provided a method for manufacturing a member to be treated comprising: a first bonding step of bonding a member to be treated containing metal oxide and a first support to each other with a first adhesive layer; a first surface processing step of processing the member to be treated containing metal oxide to form a first processed surface; a first surface contact step of bringing one of a support having adhesiveness, an adsorption support which adsorbs the member to be treated containing metal oxide, and a second adhesive layer, into contact with the first processed surface; a second bonding step of bonding the member to be treated containing metal oxide and a second support with the second adhesive layer which is in contact with the first processed surface; and a second surface processing step of processing the member to be treated containing metal oxide to form a second processed surface on a rear surface of the first processed surface, in this order, in which a step of removing the support having adhesiveness or the adsorption support is included in the first surface contact step, in a case where the support having adhesiveness or the adsorption support and the first processed surface are in contact with each other, and a first adhesive layer removing step of removing the first adhesive layer from the member to be treated containing metal oxide is included between the first surface contact step and the second bonding step or between the second bonding step and the second surface processing step.

It is preferable that the first surface contact step includes a step of supporting the first processed surface using a temporary support having adhesiveness or a adsorption support which adsorbs the member to be treated containing metal oxide, and the first adhesive layer is removed in a state where the first processed surface is supported.

It is preferable that the method further comprises a first adhesive layer degeneration step of decreasing adhesive strength of the first adhesive layer between the first surface processing step and the first adhesive layer removing step.

It is preferable that the first adhesive layer degeneration step includes at least one of exposure or heating.

It is preferable that the method further comprises a second adhesive layer degeneration step of decreasing adhesive strength of the second adhesive layer after the second surface processing step.

It is preferable that the second adhesive layer degeneration step includes at least one of exposure or heating.

It is preferable that the first adhesive layer removing step is included between the second bonding step and the second surface processing step.

It is preferable that the method further comprises a first transfer step of transferring the first processed surface of the member to be treated containing metal oxide to a first transfer support, the first adhesive layer removing step, and a second transfer step of releasing a transferred state of the first processed surface by the first transfer support, and transferring a portion other than the first processed surface of the member to be treated containing metal oxide to a second transfer support, in this order, between the first surface processing step and the second bonding step.

It is preferable that at least one of the first transfer support or the second transfer support is a temporary support having adhesiveness.

It is preferable that at least one of the first transfer support or the second transfer support is the adsorption support which adsorbs the member to be treated containing metal oxide.

It is preferable that the second bonding step is a step of sticking the second support to the second adhesive layer provided on the first processed surface of the member to be treated containing metal oxide.

It is preferable that the second bonding step is a step of sticking the member to be treated containing metal oxide to the second adhesive layer provided on the second support.

It is preferable that the first bonding step is a step of sticking the member to be treated containing metal oxide to the first adhesive layer provided on the first support.

It is preferable that the member to be treated containing metal oxide includes a conductor.

It is preferable that the conductor includes unoxidized metal.

It is preferable that the metal oxide includes a metal element other than the unoxidized metal.

It is preferable that the unoxidized metal is transition metal.

It is preferable that the metal oxide is oxide of base metal.

It is preferable that both of the first processed surface and the second processed surface are surfaces having an arithmetic average roughness equal to or smaller than 1 μm.

It is preferable that the second surface processing step is a step of processing a surface having been in contact with the first adhesive layer, among surfaces of the member to be treated containing metal oxide.

It is preferable that adhesive strength of the first adhesive layer is always smaller than adhesive strength of the second adhesive layer.

It is preferable that at least one of the first support or the second support has at least one transmission region, and a transmittance of the transmission region is 70% or more in a wavelength range of 200 to 500 nm.

It is preferable that a distance between the first processed surface and the second processed surface of the member to be treated containing metal oxide is equal to or smaller than 50 μm. It is preferable that the exposure is laser irradiation or ultraviolet irradiation.

It is preferable that at least one of the first adhesive layer or the second adhesive layer includes a material which decreases adhesiveness of the adhesive layer by heating.

According to the invention, there is provided a laminate used in the method for manufacturing a member to be treated of the invention, comprising: the first support; the first adhesive layer; and the member to be treated containing metal oxide, in this order.

In the invention, even in a case where a member to be treated containing metal oxide is a brittle substrate, a treatment such as a smoothing treatment can be stably performed on both surfaces thereof.

### BRIEF DESCRIPTION OF THE DRAWINGS

FIG. 1 is a schematic view showing one step of a first example of a method for manufacturing a member to be treated of the embodiment of the invention.

FIG. 2 is a schematic view showing another step of the first example of the method for manufacturing a member to be treated of the embodiment of the invention.

FIG. 3 is a schematic view showing still another step of the first example of the method for manufacturing a member to be treated of the embodiment of the invention.

FIG. 4 is a schematic view showing still another step of the first example of the method for manufacturing a member to be treated of the embodiment of the invention.

FIG. 5 is a schematic view showing still another step of the first example of the method for manufacturing a member to be treated of the embodiment of the invention.

FIG. 6 is a schematic view showing still another step of the first example of the method for manufacturing a member to be treated of the embodiment of the invention.

FIG. 7 is a schematic view showing still another step of the first example of the method for manufacturing a member to be treated of the embodiment of the invention.

FIG. 8 is a schematic view showing an example of a first surface processing step of the first example of the method for manufacturing a member to be treated of the embodiment of the invention.

FIG. 9 is a schematic view showing another example of the first surface processing step of the first example of the method for manufacturing a member to be treated of the embodiment of the invention.

FIG. 10 is a schematic view showing one step of a second example of the method for manufacturing a member to be treated of the embodiment of the invention.

FIG. 11 is a schematic view showing one step of a second example of the method for manufacturing a member to be treated of the embodiment of the invention.

FIG. 12 is a schematic view showing another step of the second example of the method for manufacturing a member to be treated of the embodiment of the invention.

FIG. 13 is a schematic view showing still another step of the second example of the method for manufacturing a member to be treated of the embodiment of the invention.

FIG. 14 is a schematic view showing still another step of the second example of the method for manufacturing a member to be treated of the embodiment of the invention.

FIG. 15 is a schematic view showing still another step of the second example of the method for manufacturing a member to be treated of the embodiment of the invention.

FIG. 16 is a schematic view showing still another step of the second example of the method for manufacturing a member to be treated of the embodiment of the invention.

FIG. 17 is a schematic view showing still another step of the second example of the method for manufacturing a member to be treated of the embodiment of the invention.

FIG. 18 is a schematic view showing still another step of the second example of the method for manufacturing a member to be treated of the embodiment of the invention.

FIG. 19 is a schematic plan view showing a temporary support used in the second example of the method for manufacturing a member to be treated of the embodiment of the invention.

FIG. 20 is a schematic view showing one step of a third example of the method for manufacturing a member to be treated of the embodiment of the invention.

FIG. 21 is a schematic view showing another step of the third example of the method for manufacturing a member to be treated of the embodiment of the invention.

FIG. 22 is a schematic view showing still another step of the third example of the method for manufacturing a member to be treated of the embodiment of the invention.

FIG. 23 is a schematic view showing still another step of the third example of the method for manufacturing a member to be treated of the embodiment of the invention.

FIG. 24 is a schematic view showing still another step of the third example of the method for manufacturing a member to be treated of the embodiment of the invention.

FIG. 25 is a schematic view showing still another step of the third example of the method for manufacturing a member to be treated of the embodiment of the invention.

FIG. 26 is a schematic view showing still another step of the third example of the method for manufacturing a member to be treated of the embodiment of the invention.

FIG. 27 is a schematic view showing still another step of the third example of the method for manufacturing a member to be treated of the embodiment of the invention.

FIG. 28 is a schematic view showing still another step of the third example of the method for manufacturing a member to be treated of the embodiment of the invention.

FIG. 29 is a schematic view showing one step of a fourth example of the method for manufacturing a member to be treated of the embodiment of the invention.

FIG. 30 is a schematic view showing another step of the fourth example of the method for manufacturing a member to be treated of the embodiment of the invention.

FIG. 31 is a schematic view showing still another step of the fourth example of the method for manufacturing a member to be treated of the embodiment of the invention.

FIG. 32 is a schematic view showing still another step of the fourth example of the method for manufacturing a member to be treated of the embodiment of the invention.

FIG. 33 is a schematic view showing still another step of the fourth example of the method for manufacturing a member to be treated of the embodiment of the invention.

FIG. 34 is a schematic view showing still another step of the fourth example of the method for manufacturing a member to be treated of the embodiment of the invention.

FIG. 35 is a schematic view showing still another step of the fourth example of the method for manufacturing a member to be treated of the embodiment of the invention.

FIG. 36 is a schematic view showing still another step of the fourth example of the method for manufacturing a member to be treated of the embodiment of the invention.

FIG. 37 is a schematic view showing still another step of the fourth example of the method for manufacturing a member to be treated of the embodiment of the invention.

FIG. 38 is a schematic view showing still another step of the fourth example of the method for manufacturing a member to be treated of the embodiment of the invention.

FIG. 39 is a schematic view showing still another step of the fourth example of the method for manufacturing a member to be treated of the embodiment of the invention.

FIG. 40 is a schematic view showing one step of a fifth example of the method for manufacturing a member to be treated of the embodiment of the invention.

FIG. 41 is a schematic view showing another step of the fifth example of the method for manufacturing a member to be treated of the embodiment of the invention.

FIG. 42 is a schematic view showing still another step of the fifth example of the method for manufacturing a member to be treated of the embodiment of the invention.

FIG. 43 is a schematic view showing one step of a sixth example of the method for manufacturing a member to be treated of the embodiment of the invention.

FIG. 44 is a schematic view showing another step of the sixth example of the method for manufacturing a member to be treated of the embodiment of the invention.

FIG. 45 is a plan view showing one example of a configuration of an anisotropic conductive member used in the member to be treated.

FIG. 46 is a schematic cross sectional view showing one example of a configuration of the anisotropic conductive member used in the member to be treated.

FIG. 47 is a schematic cross sectional view showing one example of a configuration of an anisotropic conductive material including the anisotropic conductive member used in the member to be treated.

FIG. 48 is a schematic view showing one step of a method for treating a member to be treated of the related art.

FIG. 49 is a schematic view showing another step of the method for treating a member to be treated of the related art.

FIG. 50 is a schematic view showing still another step of the method for treating a member to be treated of the related art.

FIG. 51 is a schematic view showing still another step of the method for treating a member to be treated of the related art.

FIG. 52 is a schematic view showing still another step of the method for treating a member to be treated of the related art.

FIG. 53 is a schematic view showing still another step of the method for treating a member to be treated of the related art.

FIG. 54 is a schematic view showing still another step of the method for treating a member to be treated of the related art.

### DESCRIPTION OF THE PREFERRED EMBODIMENTS

Hereinafter, a method for manufacturing a member to be treated and a laminate of the invention will be described in detail, with reference to suitable embodiments shown in the accompanying drawings.

The drawings described below are examples for describing the invention and the invention is not limited to the drawings shown below.

Hereinafter, a term “to” for describing a range of numerical values include numerical values on both sides. For example, in a case where ε is a numerical value α to a numerical value β, the range of ε is a range including the numerical value α and the numerical value β, and α≤ε≤β, in a case of the mathematical symbol.

An angle such as “orthogonal” includes a range of errors generally accepted in the technical field, unless otherwise noted. In addition, the “same” includes a range of errors generally accepted in the technical field.

A first example of the method for manufacturing a member to be treated will be described.

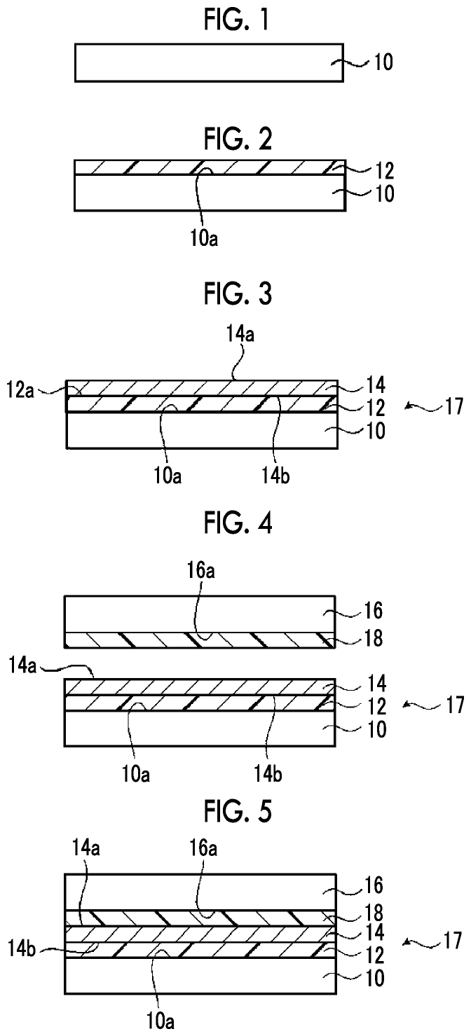

FIGS. 1 to 7 are schematic views showing the first example of the method for manufacturing a member to be treated of the embodiment of the invention in the order of steps. FIGS. 1 to 7 are schematic views respectively showing one step of the first example of the method for manufacturing a member to be treated of the embodiment of the invention.

In the first example of the method for manufacturing a member to be treated, an anisotropic conductive member will be described as an example of the member to be treated containing metal oxide, and the member to be treated containing metal oxide will be described as a substrate 14.

In the first example of the method for manufacturing a member to be treated, a disk-shaped substrate will be described as an example of the substrate 14, but the shape is not limited to the disk shape.

The anisotropic conductive member is a brittle member including an insulating base material 40 (see FIG. 8) configured with an anodic oxidation coating or the like. In addition, the member to be treated containing metal oxide is not limited to the anisotropic conductive member. The anisotropic conductive member will be described later in detail.

First, as shown in FIG. 1, a first support 10 is prepared. The first support 10 supports the substrate 14 and has a size capable of supporting the substrate 14. The first support 10 has, for example, a disk shape. A glass substrate, a quartz glass substrate, or a silicon substrate is used, for example, for the first support 10.

Next, as shown in FIG. 2, a first adhesive layer 12 is stuck to a front surface 10a of the first support 10. The first adhesive layer 12 is not particularly limited, as long as it is an adhesive layer capable of being peeled off. The adhesive layer capable of being peeled off may be a double-sided adhesive film capable of being peeled off, may be an adhesive layer having low adhesiveness, or may be an adhesive layer having adhesiveness which decreases due to at least one of exposure or heating. The adhesive layer having adhesiveness which decreases due to at least one of exposure or heating is preferable. Examples of the adhesive layer having adhesiveness which decreases due to heating include REVALPHA (registered trademark) manufactured by Nitto Denko Corporation and SOMATAC (registered trademark) manufactured by Somar Corporation. As the adhesive layer having adhesiveness which decreases due to exposure, that is, light irradiation, a material used as a general dicing tape can be used, and a light peeling tape of SELFA manufactured by Sekisui Chemical Co., Ltd. is also used as an example. In addition, the first adhesive layer 12 can also be formed by using an adhesive composition having a function of decreasing adhesiveness which is a function of decreasing adhesive strength due to at least one of exposure or heating. The exposure includes laser irradiation with laser light and ultraviolet irradiation using ultraviolet light.

In addition, the first adhesive layer 12 may have, for example, a combined configuration of a self-peeling layer and a double-sided pressure sensitive adhesive sheet. A product manufactured by Maxell Holdings, Ltd. (No. 636000 dicing tape) is used, for example, for the double-sided pressure sensitive adhesive sheet. A tape mounter is used, for example, for the application of the first adhesive layer 12.

Next, as shown in FIG. 3, for example, the substrate 14 which is the member to be treated containing metal oxide is bonded to the first adhesive layer 12, with a second surface 14b facing a front surface 12a of the first adhesive layer 12 provided on the first support 10, for example, using a vacuum sticking device (not shown), in a vacuum atmosphere.

A laminate 17 including the first support 10, the first adhesive layer 12, and the substrate 14 in this order as shown in FIG. 3 is used in the method for manufacturing a member to be treated of the invention.

A step shown in FIG. 3 is a first bonding step of bonding the member to be treated containing metal oxide and the first support 10 using the first adhesive layer 12. For the bonding of the substrate 14 to the first adhesive layer 12, specifically, sticking the substrate 14 to the first adhesive layer 12 is used.

A first surface 14a of the substrate 14 is processed in the state shown in FIG. 3 to form a first processed surface. The step of processing the first surface 14a to form the first processed surface described above is a first surface processing step. Examples of the first surface processing step include chemical mechanical polishing (CMP), a smoothing treatment by dry etching or grinding, and pattern formation on a surface.

Specifically, in the substrate 14, as shown in FIG. 8, a conductive path 42 is configured by filling an inner portion of a penetration path 41 of the insulating base material 40 with metal as a conductor. In the substrate 14, a portion 50 filled due to overflowing of metal from the penetration path 41 may be generated. The substrate 14 includes a base portion 43 in which the penetration path 41 is not formed, and the base portion 43 and the first adhesive layer 12 are in contact with each other.

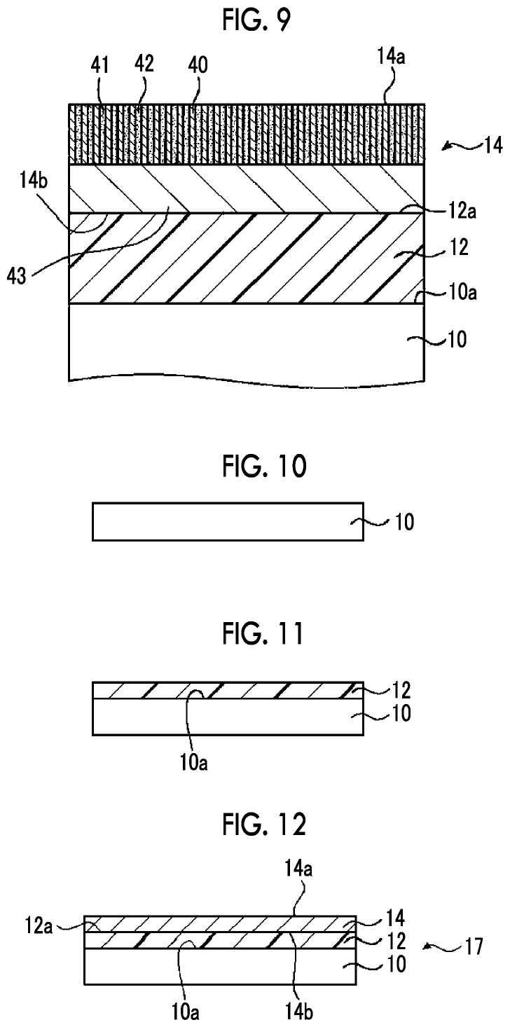

By performing the smoothing treatment on the first surface 14a of the substrate 14 in the state shown in FIG. 8, the first surface 14a is smoothed as shown in FIG. 9. In this case, the first surface 14a of the substrate 14 is preferably a surface having an arithmetic average roughness (Japanese Industrial Standards (JIS) B 0601-2001) equal to or smaller than 1 μm.

A reflectivity of the first surface 14a for finishing the smoothing treatment is determined in advance, for example, and the smoothing treatment finishes, in a case where the reflectivity becomes the predetermined value. In addition to this, the amount to be reduced is determined in advance, and the smoothing treatment may finish, in a case where the removed amount becomes the predetermined value.

Next, the first support 10 side is irradiated with laser light to decrease the adhesive strength of the first adhesive layer 12.

The step of decreasing the adhesive strength of the first adhesive layer 12 described above is a first adhesive layer degeneration step. The step of removing the first adhesive layer 12 described above is a first adhesive layer removing step.

The laser light is emitted using an yttrium aluminum garnet (YAG) laser device, for example. In a case where the first adhesive layer 12 has adhesive strength which decreases due to ultraviolet light, the ultraviolet light is emitted to decrease the adhesive strength.

The decreasing of the adhesive strength of the first adhesive layer 12 may be performed after the contact of a second adhesive layer 18 which will be described later. In a case where the first adhesive layer 12 is a self-peeling type, the timing of the removing of the first adhesive layer 12 is limited to the timing after the contact and bonding of the second adhesive layer 18 are finished.

In a case where the first adhesive layer 12 includes a self-peeling layer, the self-peeling layer is evaporated due to the laser light and the first support 10 is peeled off. In a case of the double-sided pressure sensitive adhesive sheet, this is peeled off. Accordingly, the second surface 14b of the substrate 14 is exposed.

In a case where the first adhesive layer 12 is a layer having adhesive strength which decreases due to irradiation of laser light or irradiation of ultraviolet light, the first support 10 is preferably configured with a material which transmits the laser light or the ultraviolet light. In this case, the entire portion of the first support 10 may transmit the laser light or the ultraviolet light, and the first support 10 preferably has at least one transmission region, for example. A transmittance of the transmission region is preferably 70% or more in a wavelength range of 200 to 500 nm.

The transmittance is based on Japanese Industrial Standards (JIS) R 3106-1985.

Next, as shown in FIG. 4, a second support 16 is prepared, and a second adhesive layer 18 is stuck to a front surface 16a of the second support 16. The same support as the first support 10 is used, for example, as the second support 16.

The second adhesive layer 18 has the same configuration as that of the first adhesive layer 12, for example. However, the adhesive strength of the first adhesive layer 12 is preferably always smaller than the adhesive strength of the second adhesive layer 18, in order that the second adhesive layer 18 is not peeled off from the substrate 14, in a case of peeling off the first adhesive layer 12 from the substrate 14. Here, the adhesive strength of the first adhesive layer 12 which is always smaller than the adhesive strength of the second adhesive layer 18 means that the adhesive strength is always small at least between the first bonding step and a second bonding step. That is, the adhesive strength of the first adhesive layer 12 is preferably smaller than the adhesive strength of the second adhesive layer 18, even in a state where the adhesive strength of the first adhesive layer 12 is not decreased due to the irradiation of laser light or irradiation of ultraviolet light. In addition, in the first adhesive layer removing step which will be described later, the adhesive strength of the second adhesive layer 18 is preferably always greater than the adhesive strength of the first adhesive layer 12.

The adhesive strength of the first adhesive layer 12 and the adhesive strength of the second adhesive layer 18 can be adjusted by changing the kind of adhesive, for example.

The second support 16 on which the second adhesive layer 18 is provided, is disposed so that the second adhesive layer 18 faces the first surface 14a of the substrate 14.

Next, for example, the second adhesive layer 18 is in contact with and stuck to the first surface 14a of the substrate 14 using a vacuum sticking device (not shown) in a vacuum atmosphere, and the second support 16 and the substrate 14 are bonded to each other, as shown in FIG. 5. The step of bringing the second adhesive layer 18 in contact with the first surface 14a of the substrate 14 described above is a first surface contact step, and the step of bonding the second support 16 and the substrate 14 to each other shown in FIG. 5 is a second bonding step.

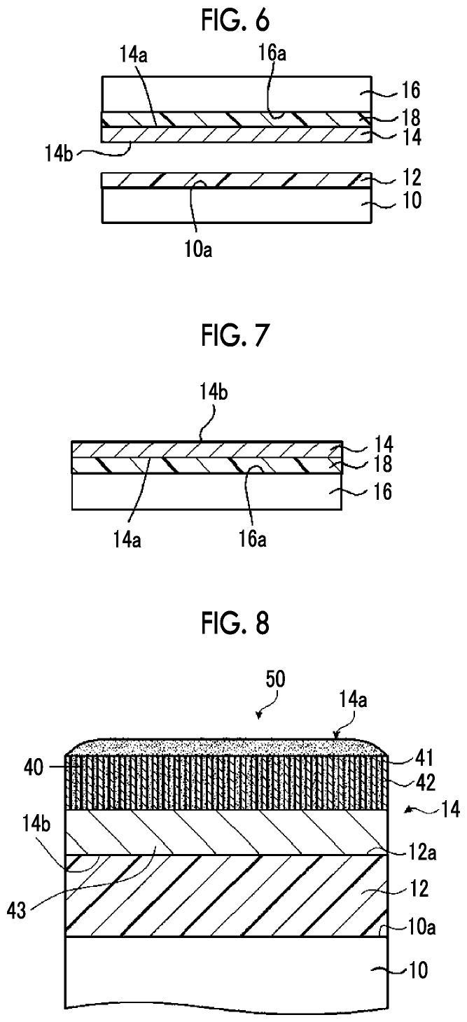

Next, the first adhesive layer 12 is removed, and the first support 10 and the substrate 14 are peeled off from each other, as shown in FIG. 6. Accordingly, the first surface 14a is bonded to the second adhesive layer 18 and the second surface 14b is exposed.

Next, as shown in FIG. 7, the second support 16 is reversed, and the smoothing treatment is performed on the second surface 14b of the substrate 14. In the smoothing treatment, a second processed surface is formed on a rear surface of the first processed surface. That is, the second surface 14b which is the rear surface of the first surface 14a of the substrate 14 is processed to obtain the second processed surface. In this case, the second surface 14b of the substrate 14 is preferably a surface having an arithmetic average roughness (Japanese Industrial Standards (JIS) B 0601-2001) equal to or smaller than 1 μm.

In addition, a distance between the first processed surface and the second processed surface is preferably equal to or smaller than 50 μm, that is, a distance Dt (see FIG. 46) between the first surface 14a of the substrate 14 and the second surface 14b of the substrate 14 is preferably equal to or smaller than 50 μm. As described above, even in a case where the thickness is small as 50 μm or less, the smoothing treatment can be performed on both surfaces.

Here, a distance (not shown) between the first surface 14a of the substrate 14 and the second surface 14b of the substrate 14 is measured by disposing a non-contact position detection sensor on both sides of the substrate 14. For the position detection sensor, a laser type displacement sensor manufactured by Keyence Corporation is used, for example.

The step of obtaining the second processed surface described above is a second surface processing step. The processing of the second surface 14b is the same as the processing of the first surface 14a described above, and therefore, the specific description is omitted.

The second surface processing step is preferably a step of processing a surface in contact with the first adhesive layer 12, among the surfaces of the member to be treated containing metal oxide.

By doing so, the smoothing treatment can be performed on both surfaces of the first surface 14a and the second surface 14b of the substrate 14 which is an anisotropic conductive member including the insulating base material 40 (see FIG. 8).

The adhesive strength of the second adhesive layer 18 is decreased by irradiation of laser light (not shown) or ultraviolet light (not shown) or heating, for example, from the second support 16 side, the second adhesive layer 18 is removed, and the substrate 14 is peeled off from the second support 16. Accordingly, the substrate 14 including the smoothed first surface 14a and the second surface 14b can be obtained. An exposure amount of ultraviolet irradiation is not limited, and is preferably 2500 to 3500 mJ/cm² and more preferably 2800 to 3300 mJ/cm².

The step of decreasing the adhesive strength of the second adhesive layer 18 by exposure or heating described above is a second adhesive layer degeneration step. In a case of decreasing the adhesive strength of the second adhesive layer 18, exposure and heating may be combined. The step of removing the second adhesive layer 18 described above is a second adhesive layer removing step.

In a case where the second adhesive layer 18 has adhesive strength which decreases due to ultraviolet light, the ultraviolet light is emitted to decrease the adhesive strength.

In a case where the second adhesive layer 18 is a layer having adhesive strength which decreases due to irradiation of laser light or irradiation of ultraviolet light, the second support 16 is preferably configured with a material which transmits the laser light or the ultraviolet light. In this case, in the same manner as in the first support 10, the entire portion of the second support 16 may transmit the laser light or the ultraviolet light, and the second support 16 preferably has at least one transmission region, for example. A transmittance of the transmission region is preferably 70% or more in a wavelength range of 200 to 500 nm.

The transmittance is based on Japanese Industrial Standards (JIS) R 3106-1985, in the same manner as in the first support 10.

The first support 10 and the second support 16 may be configured with the same material or may be configured with different materials. For example, both of the first support 10 and the second support 16 may be a quartz glass substrate or a silicon substrate. In addition, the first support 10 may be a quartz glass substrate or a silicon substrate, and the second support 16 may be a silicon substrate or a quartz glass substrate.

In a case where the substrate 14 is an anisotropic conductive member, a trimming treatment of protruding the conductive path 42 (see FIG. 46) may be performed, for example, after the smoothing treatment.

In the first example of the method for manufacturing a member to be treated, the process such as the smoothing treatment is performed on both surfaces of the substrate 14, and in a case of transferring the substrate 14, the substrate 14 is not peeled off from the first support 10 by hands. Accordingly, deformation of the substrate 14 and break of the substrate 14 are prevented. Therefore, in the process such as the smoothing treatment of both surfaces of the substrate 14, stability of production increases and a yield rate is improved. The productivity is improved and production cost is also decreased.

Next, a second example of the method for manufacturing a member to be treated will be described.

FIGS. 10 to 18 are schematic views showing the second example of the method for manufacturing a member to be treated of the embodiment of the invention in the order of steps. FIGS. 10 to 18 are schematic views respectively showing one step of the second example of the method for manufacturing a member to be treated of the embodiment of the invention. FIG. 19 is a schematic plan view showing a temporary support used in the second example of the method for manufacturing a member to be treated of the embodiment of the invention.

In FIGS. 10 to 19, the same reference numerals are used for the same components as the components shown in FIGS. 1 to 7, and the specific description is omitted.

In the second example of the method for manufacturing a member to be treated, steps shown in FIGS. 10 to 12 are the same as the steps shown in FIGS. 1 to 3 of the first example of the method for manufacturing a member to be treated, and therefore, the specific description is omitted.

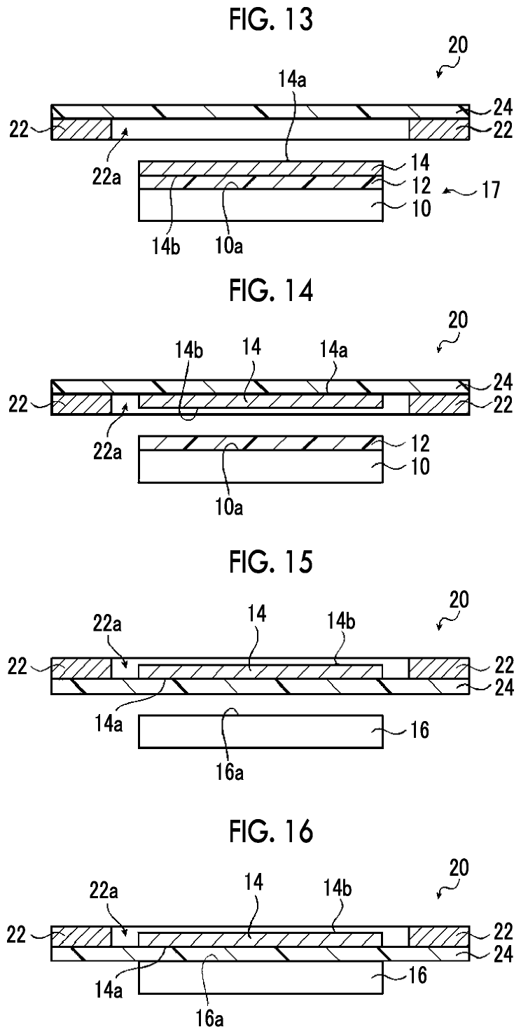

In the second example of the method for manufacturing a member to be treated, a temporary support 20 (see FIGS. 13 and 19) having adhesiveness is used. The temporary support 20 supports the substrate 14, and an adhesive sheet 24 is stuck to a frame 22 including an opening 22a, as shown in FIGS. 13 and 19.

The frame 22 is, for example, configured with stainless steel. The opening 22a is a circular hole having a diameter greater than a circumscribed circle of the substrate 14 in a plan view. The shape of the opening 22a is not particularly limited. In a case where the size of the opening 22a is small, rigidity of the frame 22 can be increased and the size of the frame 22 can also be decreased. In addition, the size of the frame 22 is preferably small, because the transportation is easily performed and the size of a sticking device such as a mounter used for the sticking can be decreased.

The adhesive sheet 24 is the second adhesive layer 18, and is, for example, configured with a material having adhesive strength on both surfaces and having adhesive strength which decreases due to at least one of exposure or heating. The adhesive sheet 24 can be configured with the same material as the first adhesive layer 12 and the second adhesive layer 18 described above.

As shown in FIG. 13, the opening 22a of the temporary support 20 is disposed to face the smoothed first surface 14a of the substrate 14.

Next, the adhesive sheet 24 is stuck to the first surface 14a of the substrate 14, for example, by using a mounter (not shown) (see FIG. 14).

The sticking of the adhesive sheet 24 to the first surface 14a of the substrate 14 can be performed in an ordinary atmosphere, and the atmosphere is not necessarily set as the vacuum atmosphere. Accordingly, the production time can be shortened and the production equipment can be simplified. In a case of sticking the adhesive sheet 24 to the first surface 14a of the substrate 14, a roller, for example, may be rolled on the adhesive sheet 24 to remove bubbles on the adhesive surface.

Next, as shown in FIG. 14, in the state where the first surface 14a which is the first processed surface of the substrate 14 is supported by the adhesive sheet 24, the first support 10 side is irradiated with laser light or ultraviolet light, in the same manner as in the first example of the method for manufacturing a member to be treated, the first adhesive layer 12 is removed, and accordingly, the substrate 14 and the first support 10 are peeled off from each other. Accordingly, the substrate 14 is bonded to the adhesive sheet 24 of the temporary support 20. The first adhesive layer degeneration step described above may be included before or after the adhesive sheet 24 comes into contact with the first surface 14a.

The laser light or ultraviolet light is emitted using an yttrium aluminum garnet (YAG) laser device or an AS ONE portable UV irradiation device, for example.

Next, as shown in FIG. 15, the temporary support 20 is reversed. The second support 16 is disposed at a position to be matched with the substrate 14.

Next, as shown in FIG. 16, the second support 16 is stuck to the adhesive sheet 24 of the temporary support 20 using a mounter (not shown), for example. The adhesive sheet 24 is provided on the first surface 14a of the substrate 14, that is, the first processed surface, and this adhesive sheet 24 is the second adhesive layer 18 (see FIG. 18). The step of sticking the second support 16 to the adhesive sheet 24 is the second bonding step. In this case, the sticking can be performed in the ordinary atmosphere, and the atmosphere is not necessarily set as the vacuum atmosphere. As described above, since it is not necessary to set the atmosphere as the vacuum atmosphere, in a case of transferring the substrate 14, the production time can be shortened and the production equipment can be simplified.

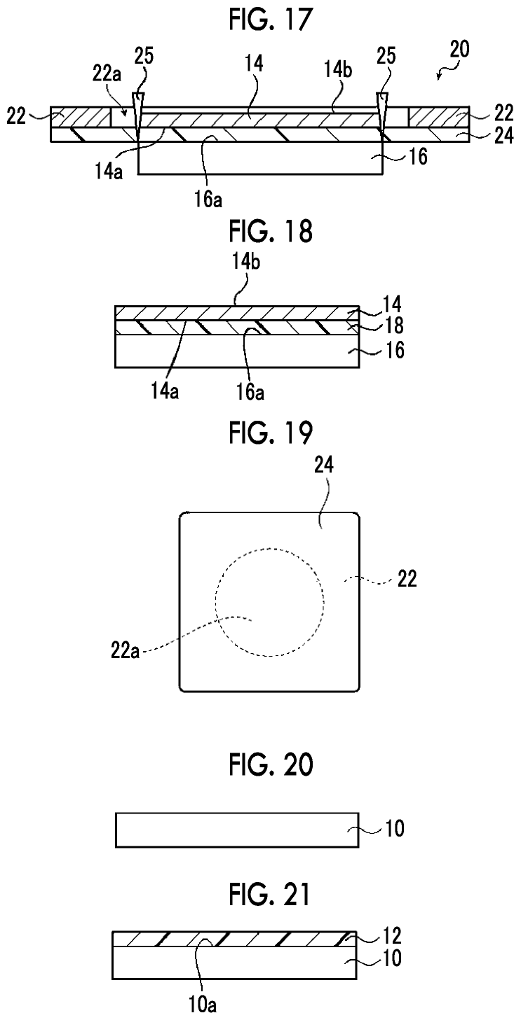

Next, as shown in FIG. 17, the adhesive sheet 24 is cut along the circumference of the substrate 14 using a cutter 25, for example. Accordingly, as shown in FIG. 18, the second support 16 and the substrate 14 are bonded to each other through the second adhesive layer 18, in a state where the second surface 14b of the substrate 14 is exposed. Next, the process is performed on the second surface 14b of the substrate 14. By doing so, the process can be performed on the first surface 14a and the second surface 14b of the substrate 14.

The adhesive strength of the second adhesive layer 18 is decreased by irradiation of laser light (not shown) or ultraviolet light (not shown) or heating, for example, from the second support 16 side, the second adhesive layer 18 is removed, and the substrate 14 is peeled off from the second support 16. Accordingly, the substrate 14 including the smoothed first surface 14a and the second surface 14b can be obtained.

In the second example of the method for manufacturing a member to be treated, the same effect as that in the first example of the method for manufacturing a member to be treated can be obtained. In addition, in the second example of the method for manufacturing a member to be treated, it is not necessary to set the atmosphere as the vacuum atmosphere, in a case of the transferring the substrate 14 using the adhesive sheet 24, the production time can be shortened, the production equipment can be simplified, and therefore, the production cost can be further reduced. The cutting of the adhesive sheet 24 is not limited to the cutter 25.

Next, a third example of the method for manufacturing a member to be treated will be described.

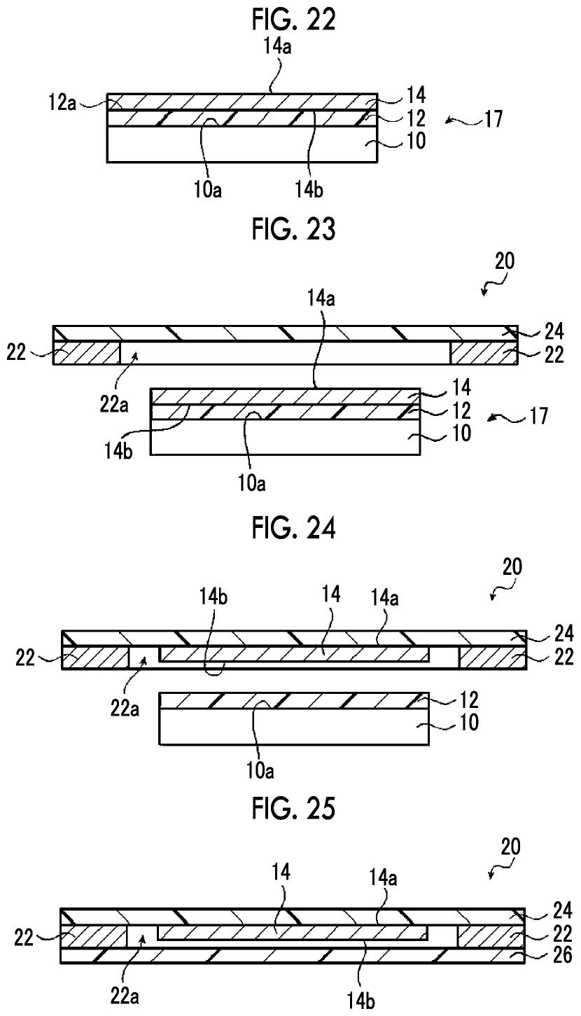

FIGS. 20 to 28 are schematic views showing the third example of the method for manufacturing a member to be treated of the embodiment of the invention in the order of steps. FIGS. 20 to 28 are schematic views respectively showing one step of the third example of the method for manufacturing a member to be treated of the embodiment of the invention.

In FIGS. 20 to 28, the same reference numerals are used for the same components as the components shown in FIGS. 10 to 19, and the specific description is omitted.

In the third example of the method for manufacturing a member to be treated, steps shown in FIGS. 20 to 22 are the same as the steps shown in FIGS. 1 to 3 of the first example of the method for manufacturing a member to be treated and the steps shown in FIGS. 10 to 12 of the second example of the method for manufacturing a member to be treated, and therefore, the specific description is omitted.

In the third example of the method for manufacturing a member to be treated, steps shown in FIGS. 23 and 24 are the same as the steps shown in FIGS. 13 and 14 of the second example of the method for manufacturing a member to be treated, and therefore, the specific description is omitted.

In the third example of the method for manufacturing a member to be treated, the first surface 14a of the substrate 14 is stuck to the adhesive sheet 24 of the temporary support 20 (see FIG. 24) and then, an adhesive sheet 26 is stuck to the frame 22 so as to cover the opening 22a, as shown in FIG. 25. The adhesive sheet 26 is stuck to the second surface 14b of the substrate 14. The step of sticking the first surface 14a of the substrate 14 to the adhesive sheet 24 of the temporary support 20 is a first transfer step.

For the adhesive sheet 26, a material having adhesive strength which decreases due to ultraviolet light is used, for example. The adhesive strength of the adhesive sheet 26 is greater than the adhesive strength of the adhesive sheet 24, and for the adhesive sheet 26, an ultraviolet (UV) peeling sheet (SELFA MP (product name) manufactured by Sekisui Chemical Co., Ltd.) which is peeled off due to ultraviolet light is used.

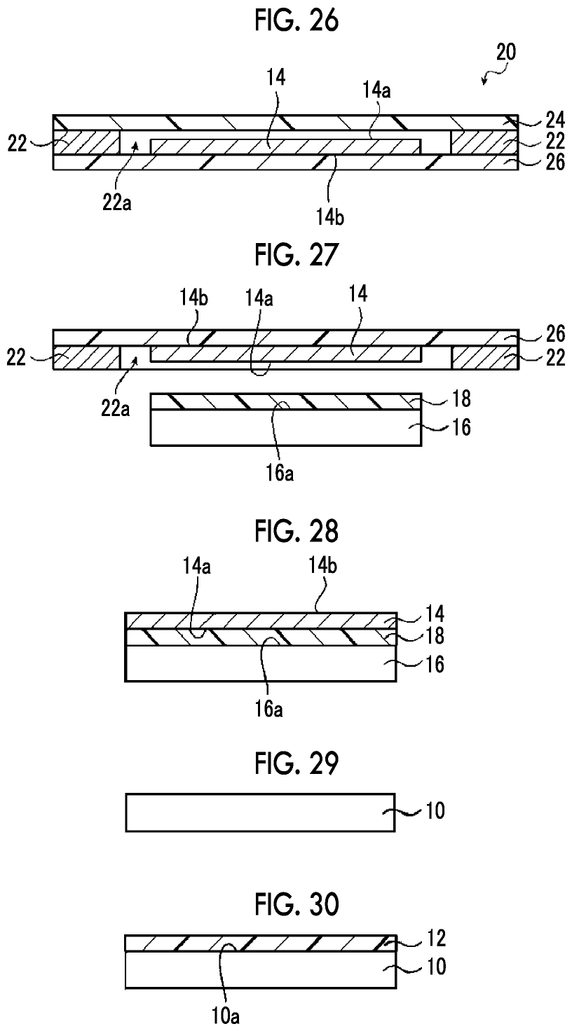

The adhesive sheet 26 has the adhesive strength greater than that of the adhesive sheet 24, and accordingly, the substrate 14 is peeled off from the adhesive sheet 24 using a difference in adhesive strength, and only the second surface 14b of the substrate 14 and the adhesive sheet 26 are stuck to each other, as shown in FIG. 26. The step of sticking the second surface 14b of the substrate 14 and the adhesive sheet 26 to each other is a second transfer step.

Next, the second support 16 including the front surface 16a on which the second adhesive layer 18 is provided is prepared.

As shown in FIG. 27, the second support 16 described above is disposed so that the second adhesive layer 18 faces the first surface 14a of the substrate 14 stuck to the adhesive sheet 26.

The first surface 14a of the substrate 14 and the second adhesive layer 18 are brought into contact with each other and stuck to each other using a mounter (not shown), as described above. Accordingly, the substrate 14 is stuck so that the first surface 14a faces the second adhesive layer 18 provided on the second support 16. The step of sticking the substrate 14 to the second adhesive layer 18 provided on the second support 16 is the second bonding step.

Next, the adhesive strength of the adhesive sheet 26 is decreased to remove the adhesive sheet 26. Accordingly, as shown in FIG. 28, the second support 16 and the substrate 14 are bonded to each other through the second adhesive layer 18, in a state where the second surface 14b of the substrate 14 is exposed. Next, the process is performed on the second surface 14b of the substrate 14. By doing so, the process can be performed on the first surface 14a and the second surface 14b of the substrate 14.

For example, the adhesive strength of the second adhesive layer 18 is decreased by heating or irradiation, for example, from the second support 16 side, the second adhesive layer 18 is removed, and the substrate 14 is peeled off from the second support 16. Accordingly, the substrate 14 including the processed first surface 14a and the second surface 14b can be obtained.

In the third example of the method for manufacturing a member to be treated, the same effect as that in the first example of the method for manufacturing a member to be treated can be obtained. In addition, in the third example of the method for manufacturing a member to be treated, it is not necessary to set the atmosphere as the vacuum atmosphere, in a case of the transferring the substrate 14 using the adhesive sheet 24 and the adhesive sheet 26, in the same manner as in the second example of the method for manufacturing a member to be treated, the production time can be shortened, the production equipment can be simplified, and therefore, the production cost can be further reduced.

Next, a fourth example of the method for manufacturing a member to be treated will be described.

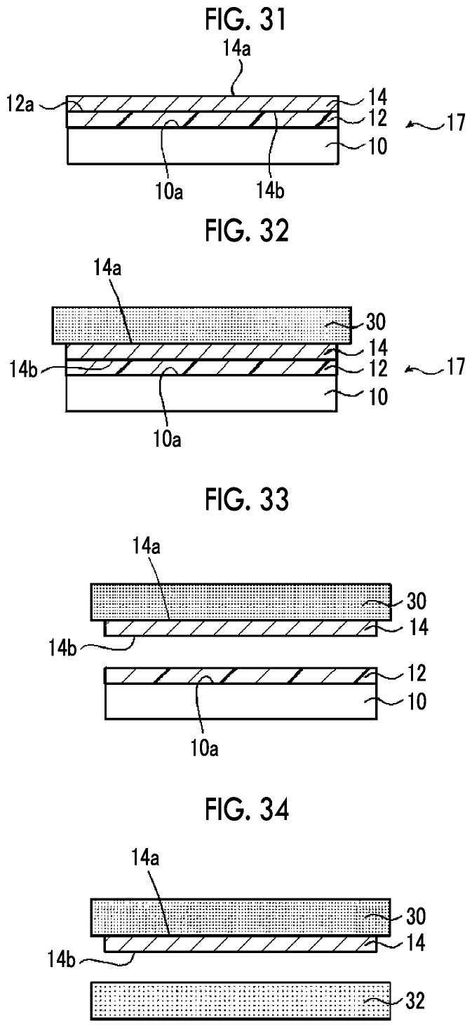

FIGS. 29 to 39 are schematic views showing the fourth example of the method for manufacturing a member to be treated of the embodiment of the invention in the order of steps. FIGS. 29 to 39 are schematic views respectively showing one step of the fourth example of the method for manufacturing a member to be treated of the embodiment of the invention.

In FIGS. 29 to 39, the same reference numerals are used for the same components as the components shown in FIGS. 10 to 19, and the specific description is omitted.

In the fourth example of the method for manufacturing a member to be treated, steps shown in FIGS. 29 to 31 are the same as the steps shown in FIGS. 1 to 3 of the first example of the method for manufacturing a member to be treated, and therefore, the specific description is omitted. In the fourth example of the method for manufacturing a member to be treated, a first transfer support 30 and a second transfer support 32 which will be described later are used for the transfer of the substrate 14.

In the fourth example of the method for manufacturing a member to be treated, as shown in FIG. 32, the first transfer support 30 is in contact with the first surface 14a of the processed substrate 14. This step is a first transfer step in which the substrate 14 is transferred to the first transfer support 30.

The first transfer support 30 is an adsorption support which adsorbs the substrate 14 and supports the contact state with the substrate 14. The first transfer support 30 is, for example, configured with a porous plate and is connected to a pressure reducing device. The contact state of the substrate 14 and the first transfer support 30 is supported by the adsorption through the first transfer support 30 due to the pressure reducing device.

In a state where the substrate 14 is adsorbed to and supported by the first transfer support 30, the first support 10 side is irradiated with laser light or ultraviolet light, the first adhesive layer 12 is removed from the substrate 14, and the first support 10 is removed from the substrate 14, as shown in FIG. 33. The first adhesive layer degeneration step may be included before or after the transfer support 30 comes into contact with the first surface 14a. Accordingly, the substrate 14 is adsorbed to the first transfer support 30.

Next, the second transfer support 32 is disposed to face the second surface 14b of the substrate 14. The second transfer support 32 is an adsorption support which adsorbs the substrate 14 and has the same configuration as that of the first transfer support 30 described above, and therefore, the specific description is omitted.

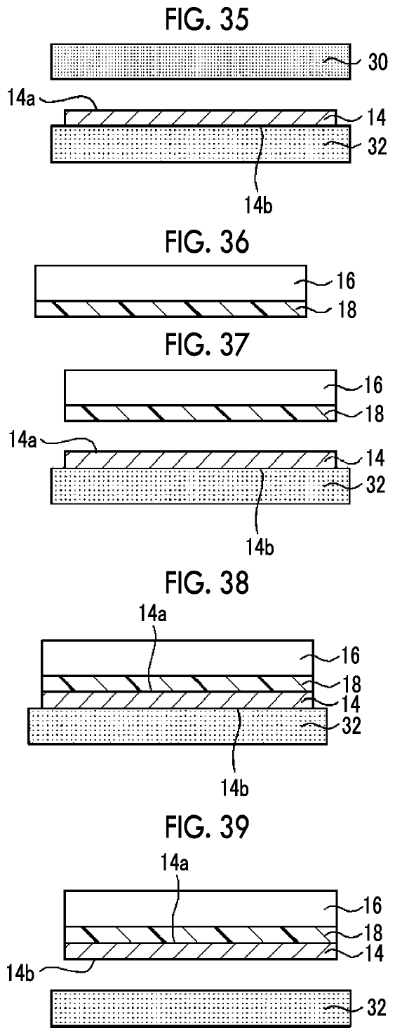

The second transfer support 32 is brought into contact with the second surface 14b which is a surface other than the first processed surface of the substrate 14, the substrate 14 is adsorbed by the second transfer support 32, and the substrate 14 is adsorbed by the first transfer support 30 and the second transfer support 32. Next, the adsorption of the substrate 14 by the second transfer support 32 is maintained, and the adsorption of the substrate 14 by the first transfer support 30 is stopped. Accordingly, a state where the first transfer support 30 and the first surface 14a of the substrate 14 are in contact with each other is released. As shown in FIG. 35, the substrate 14 is adsorbed by the second transfer support 32, in a state where the first surface 14a is exposed. This step is the second transfer step in which the substrate 14 is transferred to the second transfer support 32.

Next, as shown in FIG. 36, the second support 16 including the front surface 16a on which the second adhesive layer 18 is provided is prepared.

Next, as shown in FIG. 37, the second support 16 is disposed so that the second adhesive layer 18 faces the first surface 14a of the substrate 14 adsorbed to the second transfer support 32.

Next, as shown in FIG. 38, the first surface 14a of the substrate 14 and the second adhesive layer 18 are in contact with each other and stuck to each other using a mounter (not shown) as described above. Accordingly, the substrate 14 is stuck so that the first surface 14a faces the second adhesive layer 18 provided on the second support 16.

Next, as shown in FIG. 39, the adsorption of the substrate 14 by the second transfer support 32 is stopped. Accordingly, the second support 16 and the substrate 14 are bonded to each other through the second adhesive layer 18, in a state where the second surface 14b of the substrate 14 is exposed. The step in which the second support 16 and the substrate 14 are bonded to each other through the second adhesive layer 18 is the second bonding step.

In a case of bonding the first surface 14a of the substrate 14 and the second adhesive layer 18 to each other, it is preferable to perform the bonding in the vacuum atmosphere, in order to prevent mixing of air bubbles to a bonding interface between the first surface 14a and the second adhesive layer 18.

Next, the process is performed on the second surface 14b of the substrate 14. By doing so, the process can be performed on the first surface 14a and the second surface 14b of the substrate 14.

The adhesive strength of the second adhesive layer 18 is decreased by irradiation of laser light (not shown) or ultraviolet light (not shown) or heating, for example, from the second support 16 side, the second adhesive layer 18 is removed, and the substrate 14 is peeled off from the second support 16. Accordingly, the substrate 14 including the processed first surface 14a and the second surface 14b can be obtained.

In the fourth example of the method for manufacturing a member to be treated, the same effect as that in the first example of the method for manufacturing a member to be treated can be obtained. In addition, in the fourth example of the method for manufacturing a member to be treated, the holding state of the substrate 14 can be controlled by adsorption of the substrate 14 and the stopping of the adsorption of the substrate 14, by using the first transfer support 30 and the second transfer support 32 using the adsorption, and accordingly, the operation is simpler and the transfer of the substrate 14 can be performed faster, compared to the adhesive layer using laser light, ultraviolet light, or heating. Therefore, the production time can be shortened and the production cost can be further reduced.

In the method for manufacturing a member to be treated, the third example of the method for manufacturing a member to be treated and the fourth example of the method for manufacturing a member to be treated may be combined.

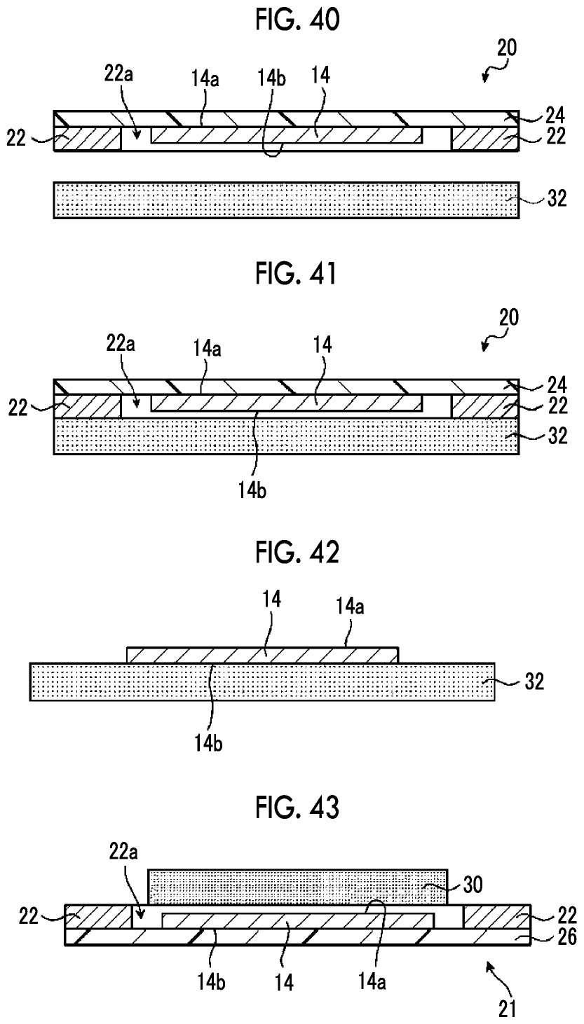

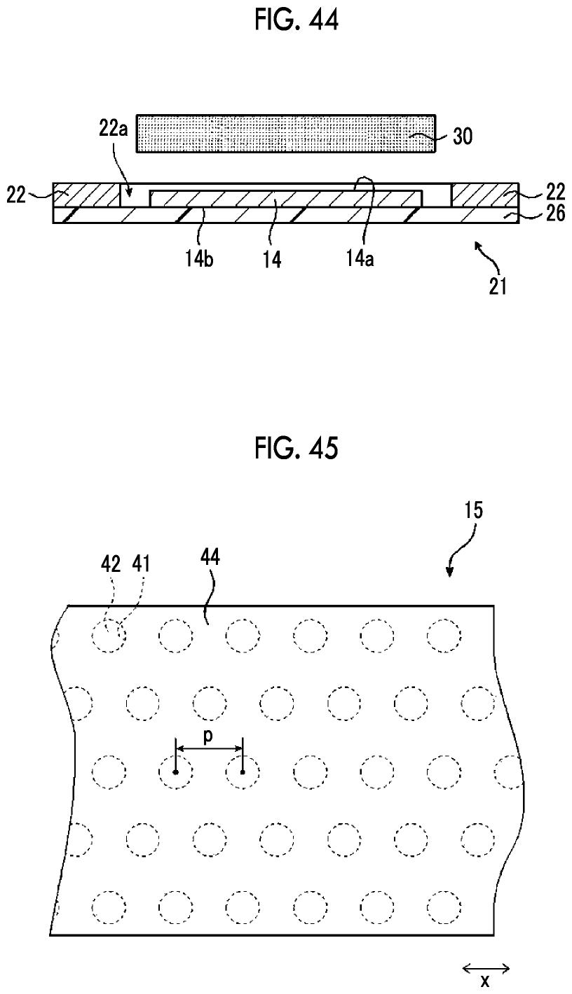

For example, in the state shown in FIG. 24 of the third example of the method for manufacturing a member to be treated, the second transfer support 32 is disposed to face the second surface 14b of the substrate 14 in the temporary support 20 (see FIG. 24) in which the substrate 14 is bonded to the adhesive sheet 24, as shown in FIG. 40.

Next, as shown in FIG. 41, the second transfer support 32 and the second surface 14b of the substrate 14 are brought into contact with each other, and the substrate 14 is adsorbed to the second transfer support 32. In this state, for example, the adhesive sheet 24 is heated, the adhesive strength of the adhesive sheet 24 is decreased and peeled off, and the adhesive sheet 24 is removed. Accordingly, as shown in FIG. 42, the second surface 14b of the substrate 14 is adsorbed to the second transfer support 32 and the first surface 14a of the substrate 14 is exposed.

As shown in FIG. 36 described above, the second support 16 including the front surface 16a on which the second adhesive layer 18 is provided is prepared. The subsequent steps are the same as in the fourth example of the method for manufacturing a member to be treated.

In the state of FIG. 34 of the fourth example of the method for manufacturing a member to be treated, the second transfer support 32 is disposed, but a temporary support 21 may be disposed as shown in FIG. 43, instead of the second transfer support 32. The temporary support 21 has the same configuration as that of the temporary support 20 described above, and therefore, the specific description is omitted.

The adhesive sheet 24 of the temporary support 21 is brought into contact with the second surface 14b of the substrate 14, and stuck using a mounter (not shown), for example.

Next, the adsorption of the first transfer support 30 is stopped, and the first transfer support 30 is separated from the substrate 14.

Next, the temporary support 21 is reversed, and the second support 16 described above is disposed so that the second adhesive layer 18 faces the first surface 14a of the substrate 14 stuck to the adhesive sheet 26, as shown in FIG. 27.

The first surface 14a of the substrate 14 and the second adhesive layer 18 are brought into contact with each other and stuck to each other using a mounter (not shown), as described above. Next, the adhesive strength is decreased to remove the adhesive sheet 26. Accordingly, as shown in FIG. 28, the second support 16 and the substrate 14 are bonded to each other through the second adhesive layer 18, in a state where the second surface 14b of the substrate 14 is exposed. Next, the process is performed on the second surface 14b of the substrate 14. By doing so, the process can be performed on the first surface 14a and the second surface 14b of the substrate 14.

Hereinafter, the anisotropic conductive member used as the substrate 14 will be described.

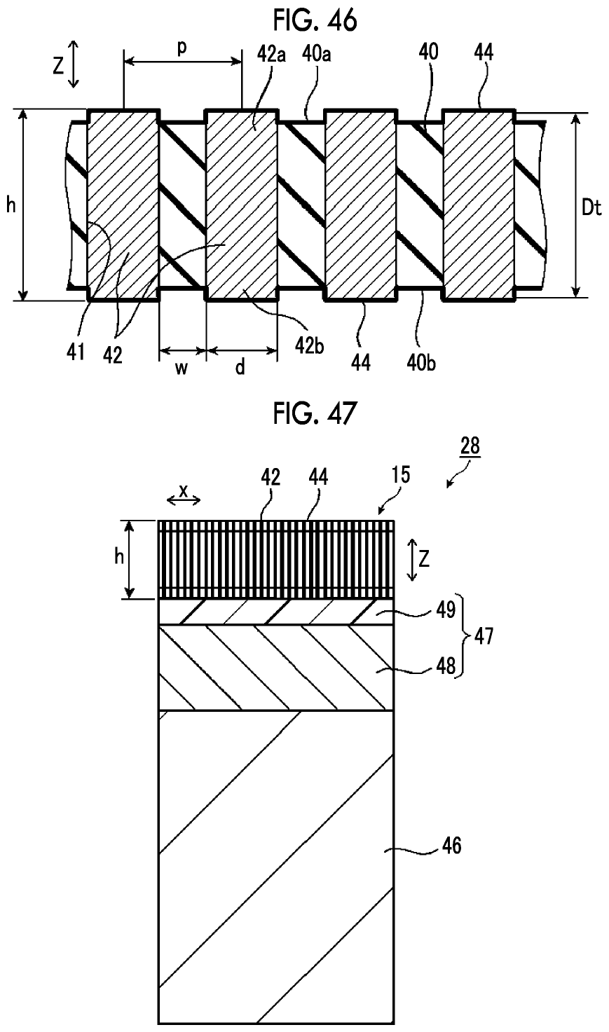

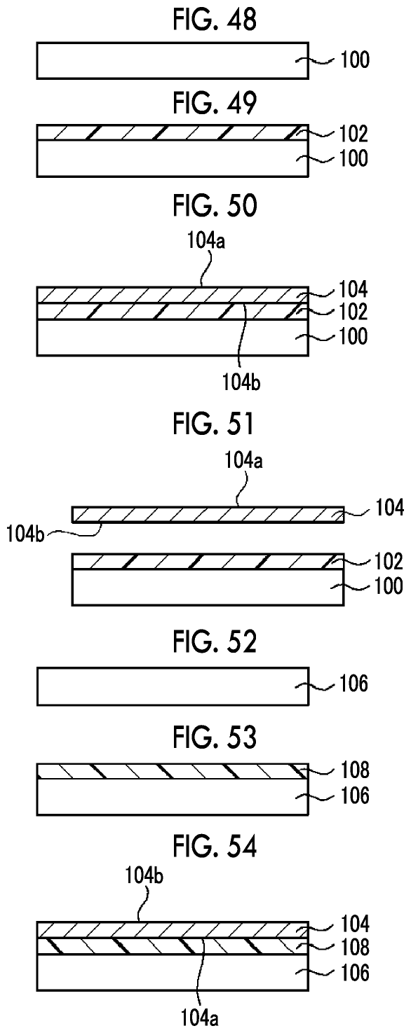

FIG. 45 is a plan view showing one example of a configuration of an anisotropic conductive member used in the member to be treated, FIG. 46 is a schematic cross sectional view showing one example of the configuration of the anisotropic conductive member used in the member to be treated, and FIG. 47 is a schematic cross sectional view showing one example of a configuration of an anisotropic conductive material including the anisotropic conductive member used in the member to be treated.

An anisotropic conductive member 15 shown in FIGS. 45 and 46 is a member including an insulating base material 40 formed of an inorganic material, and a plurality of conductive paths 42, formed of a conductive material, which penetrate in a thickness direction Z (see FIG. 46) of the insulating base material 40 and provided in a state of being electrically insulated from each other.

In the anisotropic conductive member 15, in a state where both surfaces of the substrate 14 are smoothed as described above, as shown in FIG. 46, the first surface 14a and the second surface 14b are flat surfaces and the conductive paths 42 are not protruded.

The insulating base material 40 is, for example, configured with anodic oxide of aluminum. The conductive path 42 is a path in which the inner portion of penetration path 41 penetrating in the thickness direction of the insulating base material 40 is filled with metal. For example, the conductive path 42 is configured by filling the inside of the micropore formed in an anodic oxide coating of the aluminum with metal.

Here, the expression “electrically insulated from each other” means a state where each conductive path present in the insulating base material has a sufficiently low conductivity between conductive paths in the insulating base material.

In the anisotropic conductive member 15, the conductive paths 42 are electrically insulated from each other, the conductivity is sufficiently low in a direction x orthogonal to the thickness direction Z (see FIG. 46) of the insulating base material 40, and the conductivity is provided in the thickness direction Z. As described above, the anisotropic conductive member 15 is a member showing anisotropic conductivity.

As shown in FIGS. 45 and 46, the conductive paths 42 are provided to penetrate the insulating base material 40 in the thickness direction Z, in a state of being electrically insulated from each other.

In addition, the conductive path 42 may be configured to include a protrusion portion 42a and a protrusion portion 42b protruded from front surfaces 40a and a rear surface 40b of the insulating base material 40, as shown in FIG. 46, by the trimming treatment described above. The anisotropic conductive member 15 may further include a resin layer 44 provided on the front surface 40a and the rear surface 40b of the insulating base material 40. The resin layer 44 has stickiness and also applies bondability. A length of the protrusion portion 42a and the protrusion portion 42b is preferably equal to or greater than 6 nm and more preferably 30 nm to 500 nm.

In FIG. 46, the resin layer 44 is provided on the front surfaces 40a and a rear surface 40b of the insulating base material 40, but there is no limitation thereto, and the resin layer 44 may be provided on at least one surface of the insulating base material 40.

In the same manner, as shown in FIG. 46, the protrusion portion 42a and the protrusion portion 42b are provided on both ends of the conductive path 42, but there is no limitation thereto, and the protrusion portion may be provided at least on the surface of the insulating base material 40 on a side where the resin layer 44 is provided.

A thickness h of the anisotropic conductive member 15 shown in FIG. 46 is, for example, equal to or smaller than 50 μm. In addition, a total thickness variation (TTV) of the anisotropic conductive member 15 is preferably equal to or smaller than 10 μm.

Here, the anisotropic conductive member 15 is observed with a field emission type scanning electron microscope at a magnification of 200000, a contour shape of the anisotropic conductive member 15 is obtained, and the thickness h of the anisotropic conductive member 15 is an average value of 10 measured points of the region corresponding to the thickness h.

A total thickness variation (TTV) of the anisotropic conductive member 15 is a value obtained by cutting the anisotropic conductive member 15 for each support base body 46 by dicing and observing the cross sectional shape of the anisotropic conductive member 15.

The anisotropic conductive member 15 is provided on the support base body 46, as shown in FIG. 47, for transfer, transportation, conveyance, and storage. A peeling layer 47 is provided between the support base body 46 and the anisotropic conductive member 15. The support base body 46 and the anisotropic conductive member 15 are bonded to each other to be separable by the peeling layer 47. As described above, the anisotropic conductive member 15 provided on the support base body 46 through the peeling layer 47 is referred to as an anisotropic conductive material 28.

The support base body 46 supports the anisotropic conductive member 15 and is, for example, configured with a silicon substrate. As the support base body 46, for example, a ceramic substrate such as SiC, SiN, GaN, and alumina (Al₂O₃), a glass substrate, a fiber reinforced plastic substrate, and a metal substrate can be used, in addition to the silicon substrate. The fiber reinforced plastic substrate includes Flame Retardant Type 4 (FR-4) which is a printed wiring board.

In addition, as the support base body 46, a material having flexibility and transparency can be used. Examples of the flexible and transparent support base body 46 include plastic films such as polyethylene terephthalate (PET), polycycloolefin, polycarbonate, acrylic resin, polyethylene naphthalate (PEN), polyethylene (PE), polypropylene (PP), polystyrene, polyvinyl chloride, polyvinylidene chloride, and triacetyl cellulose (TAC).

Here, the transparency means that transmittance with light at a wavelength used in the positioning is 80% or more. Accordingly, the transmittance may be low over all ranges of visible light at a wavelength of 400 to 800 nm, and the transmittance is preferably 80% or more over all ranges of visible light at a wavelength of 400 to 800 nm. The transmittance is measured by a spectrophotometer.

The peeling layer 47 is preferably a layer in which a support layer 48 and a release agent 49 are laminated. The release agent 49 is in contact with the anisotropic conductive member 15, and the support base body 46 and the anisotropic conductive member 15 are separated from the point of the peeling layer 47. In the anisotropic conductive material 28, for example, by heating to a predetermined temperature, the adhesive strength of the release agent 49 is decreased, and the support base body 46 is removed from the anisotropic conductive member 15.

For the release agent 49, for example, REVALPHA (registered trademark) manufactured by Nitto Denko Corporation and SOMATAC (registered trademark) manufactured by Somar Corporation can be used.

Hereinafter, the anisotropic conductive member 15 will be described more specifically.

[Insulating Base Material]

The insulating base material is formed of an inorganic material and is not particularly limited, as long as it has an electric resistivity (approximately 10¹⁴ Ω·cm) which is substantially the same as that of the insulating base material configuring a well-known anisotropic conductive film of the related art.

The expression “formed of an inorganic material” is for distinguishing from a polymer material configuring a resin layer which will be described later, this is not regulation for limiting to an insulating base material configured with only an inorganic material and is the regulation for including the inorganic material as a main component (50% by mass or more).

Examples of the insulating base material include a metal oxide base material, a metal nitride base material, a glass base material, a ceramic base material such as silicon carbide or silicon nitride, a carbon base material such as diamond-like carbon, a polyimide base material, and a composite material thereof. In addition thereto, the insulating base material may be, for example, a base material obtained by forming a film formed of an inorganic material containing 50% by mass or more of a ceramic base material or a carbon base material, on an organic base material including penetration holes.

The insulating base material is preferably a metal oxide base material and more preferably an anodic oxidation coating of valve metal, due to reasons that micropores having a desired average opening diameter are formed as penetration paths and conductive paths which will be described later are easily formed.

Here, specific examples of valve metal include aluminum, tantalum, niobium, titanium, hafnium, zirconium, zinc, tungsten, bismuth, and antimony. Among these, an anodic oxidation coating (base material) of aluminum is preferable, from viewpoints of excellent dimensional stability and comparatively low cost.

A space between the conductive paths of the insulating base material is preferably 5 nm to 800 nm, more preferably 10 nm to 200 nm, and even more preferably 50 nm to 140 nm. In a case where the space between the conductive paths of the insulating base material is in this range, the insulating base material sufficiently functions as an insulating barrier.

Here, the space between conductive paths is a width w (see FIG. 46) of adjacent conductive paths, and is a value obtained by observing a cross section of the anisotropic conductive member with a field emission type scanning electron microscope at a magnification of 200000, and measuring and averaging widths between adjacent conductive paths at 10 points.

[Conductive Paths]

A plurality of conductive paths are penetrated in a thickness direction of the insulating base material and are formed of a conductive material provided in a state of being electrically insulated from each other. The conductive path is a conductor.

The conductive path includes protrusion portions protruded from the surface of the insulating base material, and an end portion of the protrusion portion of each conductive path may be embedded in a resin layer which will be described later.

<Conductive Material>

The conductive material configuring the conductive path is not particularly limited, as long as it is a material having an electric resistivity equal to or smaller than 10³ Ω·cm, and as specific examples, gold (Au), silver (Ag), copper (Cu), aluminum (Al), magnesium (Mg), nickel (Ni), and indium-doped tin oxide (ITO) are suitably used.

Among these, copper, gold, aluminum, and nickel are preferable and copper and gold are more preferable, from a viewpoint of electrical conductivity. The conductive path described above, that is, the conductor is preferably configured with unoxidized metal. The unoxidized metal is, for example, transition metal, and the transition metal is, for example, the copper described above.

<Protrusion Portion>

The protrusion portion of the conductive path is a portion of the conductive path protruded from the insulating base material and an end portion of the protrusion portion is embedded in a resin layer.

An aspect ratio of the protrusion portion of the conductive path (height of protrusion portion/diameter of protrusion portion) is preferably equal to or greater than 0.5 and smaller than 50, more preferably 0.8 to 20, and even more preferably 1 to 10, from a viewpoint of sufficiently ensuring insulating properties in a plane direction, in a case where the protrusion portion is crushed, in a case of electrically connecting or physically bonding the anisotropic conductive member and an electrode to each other by a method such as pressure bonding.

A height of the protrusion portion of the conductive path is preferably equal to or greater than 20 nm and more preferably 100 nm to 500 nm, as described above, from a viewpoint of following a surface shape of a semiconductor chip or a semiconductor wafer of a connection target of the anisotropic conductive member.

The height of the protrusion portion of the conductive path is a value obtained by observing a cross section of the anisotropic conductive member with a field emission type scanning electron microscope at a magnification of 20000, and measuring and averaging the heights of the protrusion portions of the conductive paths at 10 points.

A diameter of the protrusion portion of the conductive path is a value obtained by observing a cross section of the anisotropic conductive member with a field emission type scanning electron microscope, and measuring and averaging the diameters of the protrusion portions of the conductive paths at 10 points.

<Other Shape>

The conductive path has a columnar shape, and a diameter d (see FIG. 46) of the conductive path is preferably greater than 5 nm and equal to or smaller than 10 μm, more preferably 20 nm to 1000 nm, and even more preferably equal to or smaller than 100 nm, in the same manner as the diameter of the protrusion portion.

The conductive paths are present in a state of being electrically insulated from each other by the insulating base material, and a density thereof is preferably 20000 pieces/mm², more preferably equal to or greater than 2000000 pieces/mm², even more preferably 10000000 pieces/mm², particularly preferably 50000000 pieces/mm², and most preferably 100000000 pieces/mm².

In addition, a distance p (see FIG. 45) between centers of adjacent conductive paths is preferably 20 nm to 500 nm, more preferably 40 nm to 200 nm, and even more preferably 50 nm to 140 nm.

[Resin Layer]

A resin layer is provided on the surface of the insulating base material and the conductive paths described above are embedded therein. That is, the resin layer covers the surface of the insulating base material and end portion of the conductive path protruded from the insulating base material.

The resin layer applies bondability to a connection target. The resin layer is preferably a layer which, for example, shows fluidity in a temperature range of 50° C. to 200° C. and hardens at a temperature equal to or higher than 200° C.

Hereinafter, a composition of the resin layer will be described. The resin layer contains a polymer material. The resin layer may contain an antioxidant material.

<Polymer Material>

The polymer material included in the resin layer is not particularly limited, and is preferably a thermosetting resin, from viewpoints of efficiently embedding the spaces between a semiconductor chip or a semiconductor wafer and the anisotropic conductive member and further increasing adhesiveness with a semiconductor chip or a semiconductor wafer.

Specific examples of the thermosetting resin include an epoxy resin, a phenol resin, a polyimide resin, a polyester resin, a polyurethane resin, a bismaleimide resin, a melamine resin, and an isocyanate resin.

Among these, a polyimide resin and/or an epoxy resin is preferably used, from viewpoints of improvement of insulating reliability and excellent chemical resistance.

<Antioxidant Material>

Specific example of the antioxidant material included in the resin layer include 1,2,3,4-tetrazole, 5-amino-1,2,3,4-tetrazole, 5-methyl-1,2,3,4-tetrazole, 1H-tetrazol-5-acetic acid, 1H-tetrazole-5-succinic acid, 1,2,3-triazole, 4-amino-1,2,3-triazole, 4,5-diamino-1,2,3-triazole, 4-carboxy-1H-1,2,3-triazole, 4,5-dicarboxy-1H-1,2,3-triazole, 1H-1,2,3-triazole-4-acetic acid, 4-carboxy-5-carboxymethyl-1H-1,2,3-triazole, 1,2,4-triazole, 3-amino-1,2,4-triazole, 3,5-diamino-1,2,4-triazole, 3-carboxy-1,2,4-triazole, 3,5-dicarboxy-1,2,4-triazole, 1,2,4-triazole-3-Acetic acid, 1H-benzotriazole, 1H-benzotriazole-5-carboxylic acid, benzofuroxan, 2,1,3-benzothiazole, o-phenylenediamine, m-phenylenediamine, catechol, o-aminophenol, 2-mercaptobenzothiazole, 2-mercaptobenzoimidazole, 2-mercaptobenzoxazole, melamine, and a derivative thereof.

Among these, benzotriazole and a derivative thereof are preferable.

As a benzotriazole derivative, a substituted benzotriazole including a hydroxyl group, an alkoxy group (for example, a methoxy group or an ethoxy group), an amino group, a nitro group, an alkyl group (for example, a methyl group, an ethyl group, a butyl group), a halogen atom (for example, fluorine, chlorine, bromine, or iodine) in a benzene ring of benzotriazole is used. In addition, substituted naphthalenetriazole, substituted naphthalenebistriazole and the like substituted in the same manner as naphthalenetriazole and naphthalenebistriazole can also be used.

Further, other examples of the antioxidant material included in the resin layer include higher fatty acid, higher fatty acid copper, a phenolic compound, alkanolamine, hydroquinones, a copper chelator, organic amine, organic ammonium salt which are general antioxidants.

A content of the antioxidant material included in the resin layer is not particularly limited and is preferably equal to or greater than 0.0001% by mass and more preferably equal to or greater than 0.001% by mass with respect to a total mass of the resin layer, from a viewpoint of an anticorrosive effect. In addition, the content thereof is preferably equal to or smaller than 5.0% by mass and more preferably equal to or smaller than 2.5% by mass, from a viewpoint of obtaining suitably electric resistance in the bonding process.

<Migration Prevention Material>

The resin layer preferably contains a migration prevention material, from a viewpoint of further improving insulating reliability by dropping metal ions and halogen ions which may be included in the resin layer and metal ions derived from a semiconductor chip or a semiconductor wafer.

As the migration prevention material, for example, an ion exchanger is used, and specifically, a mixture of a cation exchanger and an anion exchanger or only a cation exchanger can be used.

Here, the cation exchanger and the anion exchanger can be respectively suitably selected, for example, from inorganic ion exchangers and organic ion exchangers which will be described later.

(Inorganic Ion Exchanger)

As the inorganic ion exchanger, hydrous oxide of metal represented by hydrous zirconium oxide is used, for example.

As the kind of metal, iron, aluminum, tin, titanium, antimony, magnesium, beryllium, indium, chromium, bismuth, and the like are known, for example, in addition to zirconium.

Among these, a zirconium-based material has exchangeability regarding Cu²⁺ and Al³⁺ of cation. In addition, an iron-based material has exchangeability regarding Ag⁺ and Cu²⁺. In the same manner, a tin-based material, a titanium-based material, and an antimony-based material are cation exchangers.

Meanwhile, a bismuth-based material has exchangeability regarding Cl⁻ of anion.

In addition, a zirconium-based material shows exchangeability of anion depending on manufacturing conditions. The same applies to an aluminum-based material and a tin-based material.

As other inorganic ion exchangers, compounds such as acid salt of polyvalent metal represented by zirconium phosphate, heteropolyacid salt represented by ammonium molybdophosphate, and insoluble ferrocyanide are known.

Some of these inorganic ion exchangers are commercially available, and for example, various grades of a product name “IXE” of Toagosei Co., Ltd. are known.

In addition to the synthetic products, a powder of an inorganic ion exchanger such as zeolite or montmorillonite of natural products can also be used.

(Organic Ion Exchanger)

As the organic ion exchanger, a crosslinked polystyrene including a sulfonic acid group is used as the cation exchanger, and other crosslinked polystyrene including a carboxylic acid group, a phosphonic acid group, or a phosphinic acid group is also used.

The crosslinked polystyrene including a quaternary ammonium group, a quaternary phosphonium group, or a tertiary sulfonium group is used as the anion exchanger.

These inorganic ion exchangers and organic ion exchangers may be suitably selected by considering kinds of cations and anions to be tapped and exchange capacity of the ions. It is also possible to use a mixture of the inorganic ion exchanger and the organic ion exchanger.

The inorganic ion exchanger is preferable, because a step for manufacturing an electric element includes a heating process.

In a mixing ratio of the migration prevention material and the polymer material, the amount of the migration prevention material is preferably equal to or smaller than 10% by mass, the amount of the migration prevention material is preferably equal to or smaller than 5% by mass, and the amount of the migration prevention material is preferably equal to or smaller than 2.5% by mass, from a viewpoint of mechanical strength, for example. In addition, the amount of the migration prevention material is preferably equal to or greater than 0.01% by mass, from a viewpoint of preventing the migration in a case where a semiconductor chip or a semiconductor wafer and the anisotropic conductive member are bonded to each other.

<Inorganic Filler>

The resin layer preferably contains an inorganic filler.

The inorganic filler is not particularly limited and can be suitably selected from well-known materials, and examples thereof include kaolin, barium sulfate, barium titanate, silicon oxide powder, finely divided silicon oxide, gas phase method silica, amorphous silica, crystalline silica, fused silica, spherical silica, talc, clay, magnesium carbonate, calcium carbonate, aluminum oxide, aluminum hydroxide, mica, aluminum nitride, zirconium oxide, yttrium oxide, silicon carbide, and silicon nitride.

An average particle diameter of the inorganic filler is preferably greater than the space between the conductive paths, from viewpoints of preventing penetration of the inorganic filler between the conductive paths and further improving conductive reliability.

The average particle diameter of the inorganic filler is preferably 30 nm to 10 μm and more preferably 80 nm to 1 μm.

Here, regarding the average particle diameter, a primary particle diameter measured with a laser diffraction and scattering type particle size measurement device (MICROTRAC MT3300 manufactured by NIKKISO CO., LTD.) is set as the average particle diameter.

<Curing Agent>

The resin layer may contain a curing agent.

In a case of including the curing agent, it is more preferable to include a curing agent which is liquid at room temperature, without using a curing agent which is solid at normal temperature, from a viewpoint of preventing a bonding failure due to a surface shape of a semiconductor chip or a semiconductor wafer which is a connection target.

Here, a “solid material at room temperature” means a solid material at 25° C. and is a substance having a melting point higher than 25° C., for example.

Specific examples of the curing agent include aromatic amine such as diaminodiphenylmethane or diaminodiphenylsulfone, an imidazole derivative such as aliphatic amine or 4-methylimidazole, dicyandiamide, tetramethylguanidine, thiourea-added amine, carboxylic acid anhydride such as methylhexahydrophthalic anhydride, carboxylic acid hydrazide, carboxylic acid amide, a polyphenol compound, a novolac resin, and polymercaptan, and a liquid material at 25° C. can be suitably selected and used from these curing agents. The curing agent may be used alone or in combination of two or more kinds thereof.

The resin layer may contain various additives such as a dispersing agent, a buffer agent, and a viscosity-adjusting agent which are widely and generally added to a resin insulating film of a semiconductor package, within a range not negatively affecting the properties.

<Shape>

A thickness of the resin layer is greater than a height of the protrusion portion of the conductive path and is preferably 1 μm to 5 μm, from a viewpoint of protecting the conductive path of the anisotropic conductive member.

<Transparent Insulator>

A transparent insulator is configured with a material having a visible light transmittance of 80% or more, among materials configured with the material shown in the section of [Resin Layer]. Accordingly, specific description of each material is omitted.

In the transparent insulator, the main component (polymer material) is preferably the same as that in [Resin Layer], because the adhesiveness between the transparent insulator and the resin layer becomes excellent.

The transparent insulator preferably includes the materials in <Antioxidant Material> of [Resin Layer] and <Migration Prevention Material> of [Resin Layer].

The transparent insulator preferably includes <Inorganic Filler> of [Resin Layer], because warping of the anisotropic conductive member is reduced, in a case where a coefficient of linear expansion (CTE) is close to that of a support such as silicon.

In the transparent insulator, the polymer material and the curing agent are preferably the same as the materials in [Resin Layer], because the curing conditions such as a temperature and time become the same.

The expression “visible light transmittance of 80% or more” means that light transmittance is 80% or more in a visible light wavelength region at a wavelength of 400 to 800 nm. The light transmittance is measured using “Plastics-Determination of Total Luminous Transmittance and Reflectance” based on Japanese Industrial Standards (JIS) K 7375:2008.

[Method for Manufacturing Anisotropic Conductive Member]

A method for manufacturing the anisotropic conductive member 15 shown in FIGS. 45 and 46 is not particularly limited, and includes, for example, a conductive path formation step of forming conductive paths by providing a conductive material on penetration paths provided on an insulating base material, and a step of performing the method for manufacturing a member to be treated of the invention.

The manufacturing method further includes a trimming step of protruding the conductive path, and a resin layer formation step of forming the resin layer on a surface of the insulating base material and a protrusion portion of the conductive path after the trimming step.

[Manufacturing of Insulating Base Material]

The insulating base material preferably includes metal oxide. The insulating base material is preferably a substrate formed by performing an anodic oxidation treatment on valve metal, from a viewpoint of setting the opening diameter of the conductive path and the aspect ratio of the protrusion portion to be in the ranges described above.

The insulating base material can be manufactured by performing an anodic oxidation treatment of performing anodic oxidation of an aluminum substrate, in a case where the insulating base material is configured with anodic oxide of aluminum, for example, and a penetration treatment of penetrating holes due to micropores generated due to the anodic oxidation, after the anodic oxidation treatment.

The aluminum substrate is not particularly limited, and specific examples thereof include a pure aluminum plate; an alloy plate including aluminum as a main component and a small amount of foreign materials; a substrate obtained by performing vapor deposition of high-purity aluminum on low-purity aluminum (for example, recycling material); a substrate obtained by coating a surface of a silicon wafer, quartz, or glass with high-purity aluminum by a method of vapor deposition or sputtering; and a resin substrate obtained by laminating aluminum. Among the aluminum substrates, an aluminum purity of a surface for providing an anodic oxidation coating by the anodic oxidation treatment which will be described later is preferably equal to or greater than 99.9% by mass and more preferably equal to or greater than 99.99% by mass. In a case where the aluminum purity is in the range described above, sufficient regularity of micropore arrangement is obtained. In the invention, among the aluminum substrate, the surface to be subjected to the anodic oxidation treatment which will be described later is preferably subjected to a heat treatment, a degreasing treatment, and a mirror finishing treatment in advance.

For the aluminum substrate used in the manufacturing of the insulating base material and each treatment step performed on the aluminum substrate, the same description as disclosed in paragraphs <0041> to <0121> of JP2008-270158A can be referred to.

The metal oxide preferably includes a metal element other than unoxidized metal. The metal oxide is oxide of base metal and the oxide of base metal is, for example, oxide of aluminum. The unoxidized metal is, for example, copper, as described above.

[Conductive Path Formation Step]

The conductive path formation step is a step of providing the conductive material on the penetration paths provided on the insulating base material.

Here, as the method of providing metal on the penetration paths, for example, the same method as each method (electrolytic plating method or electroless plating method) disclosed in paragraphs <0123> to <0126> and FIG. 4 of JP2008-270158A is used.

In the electrolytic plating method or electroless plating method, an electrode layer formed of gold, nickel, or copper is preferably provided in advance. As a method for forming this electrode layer, for example, a gas phase treatment such as sputtering, a liquid layer treatment such as electroless plating, and a combined treatment thereof are used.

By a metal filling step, an anisotropic conductive member before the protrusion portion of the conductive path is formed is obtained.

Meanwhile, the conductive path formation step may be, for example, a method including an anodic oxidation treatment step of performing the anodic oxidation treatment on a surface on one side (hereinafter, also referred to as “one surface”) of an aluminum substrate and forming an anodic oxidation coating including micropores present in a thickness direction and a barrier layer present on the bottom portion of the miciropores, on the one surface of the aluminum substrate, a barrier layer removing step of removing the barrier layer of the anodic oxidation coating after the anodic oxidation treatment step, a metal filling step of filling the inner portion of the micropores with metal by performing a electroless plating treatment after the barrier layer removing step, and a substrate removing step of removing the aluminum substrate after the metal filling step to obtain a metal-filled microstructure, instead of the method disclosed in JP2008-270158A.

<Anodic Oxidation Treatment Step>

The anodic oxidation treatment step is a step of performing the anodic oxidation treatment on one surface of an aluminum substrate to form an anodic oxidation coating including micropores present in a thickness direction and a barrier layer present on the bottom portion of the miciropores, on the one surface of the aluminum substrate.

In the anodic oxidation treatment, a well-known method of the related art can be used, and a self-regulation method or a constant voltage treatment is preferably used, from viewpoints of increasing regularity of micropore arrangement and ensuring anisotropic conductivity.

Here, for the self-regulation method or a constant voltage treatment of the anodic oxidation treatment, the same treatment as each treatment disclosed in paragraphs <0056> to <0108> and FIG. 3 of JP2008-270158A can be performed.

<Barrier Layer Removing Step>

The barrier layer removing step is a step of removing the barrier layer of the anodic oxidation coating after the anodic oxidation treatment step. By removing the barrier layer, a part of the aluminum substrate is exposed through the micropores.

The method for removing the barrier layer is not particularly limited, and examples thereof include a method of electrochemically dissolving the barrier layer at a potential lower than a potential in the anodic oxidation treatment of the anodic oxidation treatment step (hereinafter, also referred to as an “electrolytic removing treatment); a method of removing the barrier layer by etching (hereinafter, also referred to as an “etching removing treatment”); and a combined method thereof (particularly, method of removing the remaining barrier layer by an etching removing treatment, after performing the electrolytic removing treatment).

<Electrolytic Removing Treatment>

The electrolytic removing treatment is not particularly limited, as long as it is an electrolytic treatment performed at a potential lower than a potential (electrolytic potential) in the anodic oxidation treatment of the anodic oxidation treatment step.

The electrolytic removing treatment can be, for example, continuously performed with the anodic oxidation treatment, by decreasing the electrolytic potential, after finishing the oxidation treatment step.

In the electrolytic removing treatment, the conditions of the electrolyte and treatment which are the same as in the well-known anodic oxidation treatment of the related art described above can be used for the conditions other than the electrolytic potential.

Particularly, in a case of performing the electrolytic removing treatment and the anodic oxidation treatment as described above, the treatment is preferably performed using the same electrolyte.

(Electrolytic Potential)

The electrolytic potential in the electrolytic removing treatment is preferably decreased continuously or in a stepwise manner to a potential lower than the electrolytic potential of the anodic oxidation treatment.

Here, a range of reduction (step width), in a case of decreasing the electrolytic potential in a stepwise manner, is preferably equal to or smaller than 10 V, more preferably equal to or smaller than 5 V, and even more preferably equal to or smaller than 2 V, from a viewpoint of a withstand voltage of the barrier layer.

In addition, a rate of voltage drop, in a case of decreasing the electrolytic potential continuously or in a stepwise manner, is preferably equal to or smaller than 1 V/sec, more preferably equal to or smaller than 0.5 V/sec, and even more preferably equal to or smaller than 0.2 V/sec, in both cases, from a viewpoint of productivity.

<Etching Removing Treatment>

The etching removing treatment is not particularly limited, and may be a chemical etching treatment of performing dissolving using an acid aqueous solution or an alkali aqueous solution or may be a dry etching treatment.

(Chemical Etching Treatment)

The removing of the barrier layer by the chemical etching treatment is, for example, a method of immersing a structure after the anodic oxidation treatment step in an acid aqueous solution or an alkali aqueous solution to fill the inner portion of micropores with the acid aqueous solution or the alkali aqueous solution, and bringing a pH (hydrogen ion exponent) buffer solution into contact with the surface of the opening side of micropores of the anodic oxidation coating, and only the barrier layer can be selectively dissolved.

Here, in a case of using the acid aqueous solution, an aqueous solution of inorganic acid such as sulfuric acid, phosphoric acid, nitric acid, or hydrochloric acid, or a mixture of these is preferably used. In addition, a concentration of the acid aqueous solution is preferably 1% by mass to 10% by mass. A temperature of the acid aqueous solution is preferably 15° C. to 80° C., more preferably 20° C. to 60° C., and even more preferably 30° C. to 50° C.

Meanwhile, in a case of using the alkali aqueous solution, at least one alkali aqueous solution selected from the group consisting of sodium hydroxide, potassium hydroxide, and lithium hydroxide is preferably used. In addition, a concentration of the alkali aqueous solution is preferably 0.1% by mass to 5% by mass. A temperature of the alkali aqueous solution is preferably 10° C. to 60° C., more preferably 15° C. to 45° C., and even more preferably 20° C. to 35° C. The alkali aqueous solution may contain zinc and other metal.

Specifically, 50 g/L of a phosphoric acid aqueous solution at 40° C., 0.5 g/L of a sodium hydroxide aqueous solution at 30° C., or 0.5 g/L of a potassium hydroxide aqueous solution at 30° C. is suitably used, for example.

As the pH buffer solution, a buffer solution corresponding to the acid aqueous solution or the alkali aqueous solution can be suitably used.

In addition, the immersing time in the acid aqueous solution or the alkali aqueous solution is preferably 8 minutes to 120 minutes, more preferably 10 minutes to 90 minutes, and even more preferably 15 minutes to 60 minutes.

(Dry Etching Treatment)

In the dry etching treatment, gas such as Cl2/Ar mixed gas is preferably used, for example.

<Metal Filling Step>

The metal filling step is a step of filling the inner portion of the micropores of the anodic oxidation coating subjected to the electroless plating treatment with metal, after the barrier layer removing step, and for example, the same method as each method (electrolytic plating method or electroless plating method) disclosed in paragraphs <0123> to <0126> and FIG. 4 of JP2008-270158A is used.

In the electrolytic plating method or electroless plating method, the aluminum substrate exposed through the micropores after the barrier layer removing step described above can be used as an electrode.

<Substrate Removing Step>

The substrate removing step is a step of removing the aluminum substrate after the metal filling step to obtain a metal-filled microstructure.

As the method for removing the aluminum substrate, for example, a method of dissolving only the aluminum substrate, without dissolving the metal filed in the inner portion of the micropores in the metal filling step and the anodic oxidation coating as the insulating base material by using a treatment liquid.

Examples of the treatment liquid include aqueous solutions of mercury chloride, a bromine/methanol mixture, a bromine/ethanol mixture, aqua regia, and a hydrochloric acid/copper chloride mixture, and among these, the hydrochloric acid/copper chloride mixture is preferable.

A concentration of the treatment liquid is preferably 0.01 mol/L to 10 mol/L and more preferably 0.05 mol/L to 5 mol/L.

A treatment temperature is preferably −10° C. to 80° C. and more preferably 0° C. to 60° C.

[Trimming Step]

The trimming step is a step of partially removing only the insulating base material on the surface of the anisotropic conductive member after the conductive path formation step and protruding the conductive path.

A step of performing the molding in a specific shape may be included, before the trimming step. In this case, for example, the molding is performed in a specific shape using a Thompson blade.

Here, the trimming treatment is not particularly limited, as long as it is performed under the condition in which the metal configuring the conductive path is not dissolved, and for example, in a case of using the acid aqueous solution, an aqueous solution of inorganic acid such as sulfuric acid, phosphoric acid, nitric acid, or hydrochloric acid, or a mixture of these is preferably used. Among these, an aqueous solution not containing chromic acid is preferable, from a viewpoint of excellent safety. A concentration of the acid aqueous solution is preferably 1% by mass to 10% by mass. A temperature of the acid aqueous solution is preferably 25° C. to 60° C.

Meanwhile, in a case of using the alkali aqueous solution, at least one alkali aqueous solution selected from the group consisting of sodium hydroxide, potassium hydroxide, and lithium hydroxide is preferably used. A concentration of the alkali aqueous solution is preferably 0.1% by mass to 5% by mass. A temperature of the alkali aqueous solution is preferably 20° C. to 50° C.

Specifically, 50 g/L of a phosphoric acid aqueous solution at 40° C., 0.5 g/L of a sodium hydroxide aqueous solution at 30° C., or 0.5 g/L of a potassium hydroxide aqueous solution at 30° C. is suitably used, for example.

In addition, the immersing time in the acid aqueous solution or the alkali aqueous solution is preferably 8 minutes to 120 minutes, more preferably 10 minutes to 90 minutes, and even more preferably 15 minutes to 60 minutes. Here, in a case where the immersion treatment (trimming treatment) for a short period of time is repeated, the immersion time is a total of each immersion time. A cleaning treatment may be performed between each immersion treatment.

In a case of strictly controlling the height of the protrusion portion of the conductive path in the trimming step, it is preferable that the insulating base material and the end portion of the conducive path are processed to have the same flat surface shape, after the conductive path formation step, and then, the insulating base material is selectively removed (trimming).

Here, examples of the method of performing the process to have the same flat surface shape include physical polishing (for example, free abrasive grain polishing, back grinding, or surface planer), electrochemical polishing, and combined polishing thereof.

In addition, after the conductive path formation step or the trimming step described above, a heat treatment can be performed, in order to reduce a strain in the conductive path generated in accordance with the filling of metal.

The heat treatment is preferably performed in a reducing atmosphere, from a viewpoint of preventing oxidation of metal, and is preferably performed at an oxygen concentration equal to or smaller than 20 Pa and more preferably performed in a vacuum state. Here, the vacuum state is a state of a space in which a gas density or air pressure is lower than that in the atmosphere.

The heat treatment is preferably performed while pressing the material, for correction.

[Resin Layer Formation Step]

The resin layer formation step is a step of forming the resin layer on a surface of the insulating base material and a protrusion portion of the conductive path after the trimming step.

Here, as the method for forming the resin layer, for example, a method for coating the surface of the insulating base material and the protrusion portion of the conductive path with a resin composition containing the antioxidant material, the polymer material, and a solvent (for example, methyl ethyl ketone), drying, and if necessary, burning is used.

The coating method of the resin composition is not particularly limited, and for example, a well-known coating method of the related art such as a gravure coating method, a reverse coating method, a die coating method, a blade coater, a roll coater, an air knife coater, a screen coater, a bar coater, a curtain coater, or a spin coater can be used.

The drying method after the coating is not particularly limited, and examples thereof include a heat treatment of performing at a temperature of 0° C. to 100° C. for several seconds to several tens of seconds in the atmosphere, and a heat treatment of performing at a temperature of 0° C. to 80° C. for several seconds to several tens of seconds under the reduced pressure.

The burning method after the drying is not particularly limited, because it varies depending on the polymer material used, and in a case of using a polyimide resin, for example, a heat treatment of performing at a temperature of 160° C. to 240° C. for 2 minutes to 60 minutes is used, and in a case of using an epoxy resin, for example, a heat treatment of performing at a temperature of 30° C. to 80° C. for 2 minutes to 60 minutes is used.

In the manufacturing method, each step described above can be performed in a sheet feeding manner, or can also be continuously treated on a web using an aluminum coil as original fabric. In a case of continuous treatment, it is preferable to provide suitable cleaning step and drying step between each step.

### EXAMPLES

Hereinafter, the characteristics of the invention will be described in detail with reference to examples. The material, the reagent, the amount used, the substance amount, the ratio, the process contents, the process procedure, and the like shown in the following examples can be suitably changed, within a range not departing from a gist of the invention. Accordingly, the range of the invention is not limited to specific examples shown below.

In the examples, a member to be treated was treated by each method for manufacturing a member to be treated in Examples 1 to 20 and Comparative Example 1 shown below. In the examples, the generation of defects and conductivity after the treatment in the method for manufacturing a member to be treated in Examples 1 to 20 and Comparative Example 1 were evaluated. The results of the generation of defects and conductivity are shown in Tables 1 to 4. In Tables 1 to 4, “-” indicates no results.

In addition, each member used in the method for manufacturing a member to be treated in Examples 1 to 20 and Comparative Example 1 are shown in Tables 1 to 4. The adhesive strength shown in Tables 1 to 4 is a value measured under the conditions of a peeling angle of 180° and a tension rate of 300 mm/min.

Evaluation methods of the generation of defects and conductivity will be described.

[Generation of Defects]

The generation of defects was evaluated with the number of defects such as cracks having a size equal to or greater than 30 μm generated in the member to be treated, from a previous step (<circular machining step> which will be described later) of the step regarding the invention to a second polishing treatment step.

The defect was measured as shown below.

The member to be treated which will be described later in detail does not transmit infrared light, and accordingly, cracks on the member to be treated can be accurately detected, in a case of using the infrared light.

An inspecting image of the whole area of the member to be treated in a plan view was obtained with an infrared microscope, a binarization process was performed on the obtained inspecting image, and a binarized image of the inspecting image was obtained. A length of a black portion of the binarized image was measured. From the black portion, the defects were extracted by setting 30 μm as a threshold value.

As the infrared microscope, a semiconductor/FPD inspection microscope MX 61 (product name) manufactured by Olympus Corporation was used. As the lens, an object lens for observation in infrared region (700 nm to 1300 nm) LMRLN5XIR (product name) manufactured by Olympus Corporation was used. As the stage, automatic motorized XY stage for an upright microscope manufactured by Marzhauser was used.

The generation of defects was shown with the unit of N pieces/100 cm² and was evaluated based on the following evaluation standard.
A: N<5
B: 5≤N<20
C: 20≤N<100
D: 100≤N

[Conductivity]

RM3542 manufactured by Hioki E.E. Corporation was used on a front surface and a rear surface of the member to be treated, after the second polishing treatment step is finished, through a metal connection portion, and a resistivity of the member to be treated, after the second polishing treatment step is finished, in a thickness direction was calculated by a four-terminal method. The conductivity was evaluated based on the following evaluation standard using the resistivity described above.
A: Resistivity is stably smaller than 1×10⁻⁴ Ω·m.
B: Resistivity is stably equal to or greater than 1×10⁻⁴ Ω·m.
C: Resistivity varies or stable resistivity is not shown.
D: Not electrically connected.

Hereinafter, Examples 1 to 20 will be described.

### Example 1

In Example 1, first, a self-peeling tape (first adhesive, SELFA manufactured by Sekisui Chemical Co., Ltd.) was stuck to a disk-shaped quartz glass substrate having a diameter of 200 mm and a thickness of 1 mm. The member to be treated was stuck thereon. At this time, in the sticking of the member to be treated, a vacuum sticking device (modified product manufactured by Ayumi Industry Co., Ltd.) was used. After that, a first surface of the member to be treated was treated by chemical mechanical polishing.

Meanwhile, a heat peeling sheet (second adhesive, REVALPHA manufactured by Nitto Denko Corporation) was stuck to a disk-shaped silicon (Si) substrate having a diameter of 200 mm and a thickness of 0.775 mm by a mounter, and then, the member to be treated which is treated by the chemical mechanical polishing was stuck by the vacuum sticking device. Then, the member to be treated was peeled off from the quartz glass substrate side by decreasing adhesive strength of the self-peeling tape with ultraviolet irradiation (irradiation amount of 3000 mJ/cm²), and the exposed untreated surface (second surface) was treated with the chemical mechanical polishing. The member to be treated will be described later. The ultraviolet irradiation was shown as UV irradiation in Tables 1 to 4. In addition, the first adhesive configures a first adhesive layer and the second adhesive configures a second adhesive layer.

The treatment of the chemical mechanical polishing described above was performed four hours using a chemical mechanical polishing (CMP) slurry of PNANERLITE-7000 manufactured by Fujimi Incorporated. A thickness of the member to be treated after the chemical mechanical polishing is 40 μm and a surface roughness of the first surface and the second surface was 0.1 μm as arithmetic average roughness.

### Example 2

In Example 2, first, a self-peeling tape (first adhesive) was stuck to a quartz glass substrate, the member to be treated was stuck thereon, and a first surface was treated by chemical mechanical polishing, in the same manner as in Example 1.

A doughnut-shaped frame which has a sufficiently greater hole than that of the quartz glass substrate and is formed with a stainless steel plate having a thickness of 1 mm was prepared, and the heat peeling sheet (second adhesive) described above was stuck to the frame. The heat peeling sheet was stuck to the polished member to be treated using a mounter, and then, the member to be treated was peeled off from the quartz glass substrate side by decreasing adhesive strength of the self-peeling tape with ultraviolet irradiation (irradiation amount of 3000 mJ/cm²). Next, the frame was reversed and stuck to the silicon substrate using a mounter, and the heat peeling sheet was cut to have a size of the silicon substrate and a circular shape with a cutter. Then, the exposed untreated surface was treated with the chemical mechanical polishing.

The chemical mechanical polishing is as described in <Example 1>.

### Example 3

In Example 3, first, a self-peeling tape (first adhesive) was stuck to a quartz glass substrate, the member to be treated was stuck thereon, and a first surface was treated by chemical mechanical polishing, in the same manner as in Example 1.

A doughnut-shaped frame which has a sufficiently greater hole than that of the quartz glass substrate and is formed with a stainless steel plate having a thickness of 1 mm was prepared, and an intermediate temporary adhesive target 1 (SPV-200 manufactured by Nitto Denko Corporation) was stuck to the frame. The intermediate temporary adhesive target 1 was stuck to the first surface of the member to be treated which is treated by the chemical mechanical polishing using a mounter, and then, the member to be treated was peeled off by decreasing adhesive strength of the self-peeling tape with ultraviolet irradiation. On the rear surface of the frame, an intermediate temporary adhesive target 2 (REVALPHA manufactured by Nitto Denko Corporation) was stuck to the untreated surface of the member to be treated. By sticking the intermediate temporary adhesive target 2 to the untreated surface, the intermediate temporary adhesive target 1 among the intermediate temporary adhesive target 1 and the intermediate temporary adhesive target 2 was peeled off, by using a difference in adhesive strength between the intermediate temporary adhesive target 1 and the intermediate temporary adhesive target 2.

Meanwhile, the heat peeling sheet (second adhesive) was stuck to the silicon substrate with a mounter. After that, the silicon substrate was stuck to the first surface of the member to be treated, in a state of being stuck to the intermediate temporary adhesive target 2 of the frame, through the heat peeling sheet with a mounter. The intermediate temporary adhesive target 2 was peeled off from the quartz glass substrate side with ultraviolet irradiation (irradiation amount of 3000 mJ/cm²), and the exposed untreated surface was treated with the chemical mechanical polishing.

The chemical mechanical polishing is as described in <Example 1>.

### Example 4

In Example 4, first, a self-peeling tape (first adhesive) was stuck to a quartz glass substrate, the member to be treated was stuck thereon, and a first surface was treated by chemical mechanical polishing, in the same manner as in Example 1.

A first porous adsorption plate was brought into contact with and is adsorbed to a polished surface of the member to be treated in the vacuum sticking device, and the member to be treated was peeled off by decreasing adhesive strength of the self-peeling tape with ultraviolet irradiation. Then, the untreated surface of the member to be treated was adsorbed by a second adsorption plate, and then, the first adsorption plate was peeled off from the member to be treated by releasing the adsorption of the first adsorption plate.

Meanwhile, the heat peeling sheet (second adhesive) was stuck to the silicon substrate with a mounter, and then, the member to be treated adsorbed by the second adsorption plate was stuck to the silicon substrate in the vacuum sticking device. The second adsorption plate was peeled off from the member to be treated by releasing the adsorption of the second adsorption plate. Then, the exposed untreated surface was treated with the chemical mechanical polishing.

The chemical mechanical polishing is as described in <Example 1>.

### Example 5

Example 5 is the same as Example 1, except that SRL0759 (product name) (double-sided slightly pressure sensitive adhesive sheet) manufactured by LINTEC Corporation was used as the self-peeling tape (first adhesive) and the member to be treated was peeled off without the ultraviolet irradiation, compared to Example 1.

### Example 6

Example 6 is the same as Example 1, except that SOMATAC (registered trademark) PS-1151CR (product number) manufactured by Somar Corporation was used as the self-peeling tape (first adhesive), compared to Example 1. The self-peeling tape (SOMATAC (registered trademark) PS-1151CR (product number) manufactured by Somar Corporation) used in Example 6 was continuously heated to 60° C., and in a case where the heating is stopped, the adhesive strength decreases. Therefore, “cooling (60° C. 20° C.)” was shown in a column of “adhesive layer degeneration condition” of “first support” of Table 2.

### Example 7

Example 7 is the same as Example 1, except that SRL0759 (product name) (double-sided slightly pressure sensitive adhesive sheet) manufactured by LINTEC Corporation was used as the self-peeling tape (second adhesive), compared to Example 1.

### Example 8

Example 8 is the same as Example 1, except that SOMATAC (registered trademark) PS-1151CR (product number) manufactured by Somar Corporation was used as the self-peeling tape (second adhesive), compared to Example 1. The self-peeling tape in Example 8 was continuously heated to 60° C. as described above, and in a case where the heating is stopped, the adhesive strength decreases. Therefore, “cooling (60° C. 20° C.)” was shown in a column of “adhesive layer degeneration condition” of “second support” of Table 2.

### Example 9

Example 9 is the same as Example 1, except that the micropores of the member to be treated were filled with nothing, compared to Example 1.

### Example 10

Example 10 is the same as Example 1, except that the micropores of the member to be treated were filled with indium tin oxide (ITO), instead of copper, compared to Example 1. The vapor deposition was used in the filling of the micropores of the member to be treated with indium tin oxide (ITO). In addition, “ITO” was shown in a column of “conductor type” in Table 2.

### Example 11

Example 11 is the same as Example 1, except that the micropores of the member to be treated were filled with aluminum, instead of copper, compared to Example 1. The vapor deposition was used in the filling of the micropores of the member to be treated with aluminum.

### Example 12

Example 12 is the same as Example 1, except that the micropores of the member to be treated were filled with magnesium, instead of copper, compared to Example 1. The vapor deposition was used in the filling of the micropores of the member to be treated with magnesium.

### Example 13

Example 13 is the same as Example 1, except that the surface roughness of the first surface and the second surface of the member to be treated after the chemical mechanical polishing was 0.5 μm as arithmetic average roughness, compared to Example 1.

### Example 14

Example 14 is the same as Example 1, except that a silicon substrate having a diameter of 200 mm and a thickness of 0.775 mm was used instead of the quartz glass substrate having a diameter of 200 mm and a thickness of 1 mm, SOMATAC (registered trademark) PS-1151CR (product number) manufactured by Somar Corporation was used as the self-peeling tape (first adhesive), the quartz glass substrate having a diameter of 200 mm and a thickness of 1 mm was used instead of a disk-shaped silicon (Si) substrate having a diameter of 200 mm and a thickness of 0.775 mm, and the self-peeling tape (SELFA manufactured by Sekisui Chemical Co., Ltd.) was used as the heat peeling sheet (second adhesive), compared to Example 1.

### Example 15

Example 15 is the same as Example 1, except that the thickness of the member to be treated after the chemical mechanical polishing was set as 80 μm, compared to Example 1.

### Example 16

Example 16 is the same as Example 1, except that the laser irradiation was used for decreasing the adhesive strength of the self-peeling tape (first adhesive), compared to Example 1. In the laser irradiation, MD-X1500 (model type) manufactured by Keyence Corporation was used. The laser irradiation was performed at a wavelength of 380 nm, an output of 5 W, a scanning speed of 3 m/sec, and a feeding width of 50 μm.

### Example 17

Example 17 is the same as Example 1, except that the quartz glass substrate having a diameter of 200 mm and a thickness of 1 mm was used instead of a disk-shaped silicon (Si) substrate having a diameter of 200 mm and a thickness of 0.775 mm, and the self-peeling tape (SELFA manufactured by Sekisui Chemical Co., Ltd.) was used as the heat peeling sheet (second adhesive) on the quartz glass substrate, compared to Example 1.

### Example 18

Example 18 is the same as Example 1, except that the hole diameter of the micropores was 100 nm and the density of the micropores was 5000000 pieces/cm², compared to Example 1. In Example 18, the manufacturing was performed in the same manner as in Example 1, except that the voltage was changed in <anodic oxidation treatment step> which will be described later.

### Example 19

Example 19 is the same as Example 1, except that the mechanical polishing was performed, instead of the chemical mechanical polishing of the member to be treated, compared to Example 1. The mechanical polishing is the same as the treatment of the chemical mechanical polishing described above, except that the CMP slurry was changed to a diamond polishing agent. The surface roughness of the first surface and the second surface of the member to be treated after the chemical mechanical polishing was equal to or greater than 1 μm as arithmetic average roughness.

### Example 20

Example 20 is the same as Example 1, except that the thickness of the quartz glass substrate was set as 2 mm and the thickness of the silicon substrate was set as 1.5 mm, compared to Example 1.

### Comparative Example 1

Comparative Example 1 is the same as Example 1, except that the order of the step of sticking the member to be treated to the heat peeling sheet and the step of peeling off the member to be treated from the self-peeling tape of Example 1 was changed, compared to Example 1.

Hereinafter, the members to be treated used in Examples 1 to 20 and Comparative Example 1 will be described. The member to be treated was configured with aluminum oxide.

An aluminum oxide material which is the member to be treated was manufactured by the following method.

<Electrolytic Polishing Treatment Step>

A high-purity aluminum substrate (manufactured by Sumitomo Light Metal Industries, Ltd. (manufactured by UACJ Corporation), purity: 99.99% by mass, thickness: 0.2 mm) was used as a substrate. The aluminum substrate was cut to have an area with a diameter of 220 mm so as to perform the anodic oxidation treatment, and an electrolytic polishing treatment was performed using an electrolytic polishing liquid having the following composition under conditions of a voltage of 25 V, a liquid temperature of 65° C., and a liquid flow rate of 3.0 m/min. The cathode was set as a carbon electrode, and GP0110-30R (manufactured by TAKASAGO LTD.) was used as a power source. In addition, a flow rate of the electrolyte was measured using a vortex flow monitor FLM22-10PCW manufactured by AS ONE.

(Electrolytic Polishing Liquid Composition)
85% by mass phosphoric acid (reagent manufactured by Wako Pure Chemical Industries, Ltd.): 660 mL (milliliters)
Pure water: 160 mL
Sulfuric acid: 150 mL
Ethylene glycol: 30 mL

<Anodic Oxidation Treatment Step>

Next, a pre-anodic oxidation treatment was performed on the aluminum substrate after the electrolytic polishing treatment with an electrolyte of 0.30 mol/L (liter) of sulfuric acid under conditions of a voltage of 25 V, a liquid temperature of 15° C., and a liquid flow rate of 3.0 m/min for 5 hours. Then, a film removing treatment of immersing the aluminum substrate after the pre-anodic oxidation treatment in a mixed aqueous solution (liquid temperature: 50° C.) of 0.2 mol/L of chromic anhydride and 0.6 mol/L of phosphoric acid for 12 hours. Then, a re-anodic oxidation treatment was performed with an electrolyte of 0.30 mol/L of sulfuric acid under conditions of a voltage of 25 V, a liquid temperature of 15° C., and a liquid flow rate of 3.0 m/min for 1 hour. In both of the pre-anodic oxidation treatment and re-anodic oxidation treatment, the cathode was set as a stainless steel electrode, and GP0110-30R (manufactured by TAKASAGO LTD.) was used as a power source. NeoCool BD36 (manufactured by Yamato Scientific Co., Ltd.) was used as a cooling device, and a pair stirrer PS-100 (manufactured by Tokyo Rikakikai Co., Ltd.) was used as a stirring heating device. In addition, a flow rate of the electrolyte was measured using a vortex flow monitor FLM22-10PCW manufactured by AS ONE.

<Penetration Treatment Step>

Next, the aluminum substrate was dissolved by immersing in a 20% by mass of mercury chloride aqueous solution (corrosive sublimate) at 20° C. for 3 hours, the bottom of the anodic oxide coating was removed by immersing in 5% by mass of phosphoric acid at 30° C. for 30 minutes, and a structure (insulating base material) formed of the anodic oxide coating including penetration holes formed of micropores was manufactured. The hole diameter of micropores was 70 nm and the density of micropores was 10000000 pieces/cm².

<Metal Filling Treatment Step>

Next, a copper electrode was bonded to one surface of the structure after the penetration treatment, and the electrolytic plating was performed by setting the copper electrode was set as the negative electrode and platinum as the positive electrode. The constant voltage pulse electrolysis was performed using the mixed solution of copper sulfate/sulfuric acid/hydrochloric acid=200/50/15 (g/L) as the electrolyte in a state where the temperature was held at 25° C., and accordingly, a structure in which penetration holes are filled with copper (anisotropic conductive member precursor) was manufactured. Here, the constant voltage pulse electrolysis was performed using a plating device manufactured by Yamamoto-Ms Co., Ltd. and using a power source (HZ-3000) manufactured by Hokuto Denko Corp., by confirming a deposition potential by performing cyclic voltammetry in a plating solution and setting a potential on a coating side as −2 V. The pulse waveform of the constant voltage pulse electrolysis was a rectangular wave. Specifically, the electrolysis treatment in which the electrolysis time of one time was 60 seconds was performed five times by setting a rest time of 40 seconds between each electrolysis treatment, so that the total treatment time of the electrolysis becomes 300 seconds.

<Circular Machining Step>

The member subjected to the metal filling treatment was washed with water and dried and punched to have a circular shape having a diameter of 199 mm with a Thompson blade using UDP-3000 manufactured by Fujishoko-Machinery Co., Ltd.

TABLE 1

| | | Example 1 | Example 2 | Example 3 | Example 4 | Example 5 |
|---|---|---|---|---|---|---|
| Member to be treated | Metal oxide type | Aluminum oxide | Aluminum oxide | Aluminum oxide | Aluminum oxide | Aluminum oxide |
| | Thickness before | 0.1 mm | 0.1 mm | 0.1 mm | 0.1 mm | 0.1 mm |
| | treatment | | | | | |
| | Size of member to be | Disk shape having diameter of | Disk shape having diameter of | Disk shape having diameter of | Disk shape having diameter of | Disk shape having diameter of |
| | treated | 200 mm | 200 mm | 200 mm | 200 mm | 200 mm |
| | Hole diameter of | 70 nm | 70 nm | 70 nm | 70 nm | 70 nm |
| | micropores | | | | | |
| | Density of micropores | 10000000 pieces/mm² | 10000000 pieces/mm² | 10000000 pieces/mm² | 10000000 pieces/mm² | 10000000 pieces/mm² |
| | Conductor type | Copper | Copper | Copper | Copper | Copper |
| | Treatment means | Chemical mechanical | Chemical mechanical | Chemical mechanical | Chemical mechanical | Chemical mechanical |
| | (first surface) | polishing | polishing | polishing | polishing | polishing |
| | Treatment means | Chemical mechanical | Chemical mechanical | Chemical mechanical | Chemical mechanical | Chemical mechanical |
| | (second surface) | polishing | polishing | polishing | polishing | polishing |
| | Thickness after | 40 μm | 40 μm | 40 μm | 40 μm | 40 μm |
| | treatment of both | | | | | |
| | surfaces | | | | | |
| | Arithmetic average | 0.1 μm | 0.1 μm | 0.1 μm | 0.1 μm | 0.1 μm |
| | roughness after | | | | | |
| | treatment of both | | | | | |
| | surfaces (first surface) | | | | | |
| | Arithmetic average | 0.1 μm | 0.1 μm | 0.1 μm | 0.1 μm | 0.1 μm |
| | roughness after | | | | | |
| | treatment of both | | | | | |
| | surfaces (second | | | | | |
| | surface) | | | | | |
| Treatment | Treatment aspect | Manufacturing method 1 | Manufacturing method 2 | Manufacturing method 3 | Manufacturing method 4 | Manufacturing method 1 |
| method | | | | | | |
| First support | Material of support | Quartz glass | Quartz glass | Quartz glass | Quartz glass | Quartz glass |
| | Size of support | Disk shape having diameter of | Disk shape having diameter of | Disk shape having diameter of | Disk shape having diameter of | Disk shape having diameter of |
| | | 200 mm | 200 mm | 200 mm | 200 mm | 200 mm |
| | Thickness of support | 1 mm | 1 mm | 1 mm | 1 mm | 1 mm |
| | First adhesive | SELFA (manufactured by | SELFA (manufactured by | SELFA (manufactured by | SELFA (manufactured by | SRL0759 (double-sided |
| | | SEKISUI CHEMICAL | SEKISUI CHEMICAL | SEKISUI CHEMICAL | SEKISUI CHEMICAL | slightly pressure sensitive |
| | | CO., LTD) | CO., LTD) | CO., LTD) | CO., LTD) | adhesive sheet manufactured |
| | | | | | | by LINTEC Corporation) |
| | Adhesive layer | UV irradiation: 3000 mJ/cm² | UV irradiation: 3000 mJ/cm² | UV irradiation: 3000 mJ/cm² | UV irradiation: 3000 mJ/cm² | None |
| | degeneration | | | | | |
| | condition | | | | | |
| | Adhesive strength | 10 N/20 mm | 10 N/20 mm | 10 N/20 mm | 10 N/20 mm | 0.7 N/20 mm |
| | before degeneration | | | | | |
| | Adhesive strength | Equal to or smaller than | Equal to or smaller than | Equal to or smaller than | Equal to or smaller than | 0.7 N/20 mm |
| | after degeneration | 0.1 N/20 mm | 0.1 N/20 mm | 0.1 N/20 mm | 0.1 N/20 mm | |
| Second | Material of support | Silicon | Silicon | Silicon | Silicon | Silicon |
| support | Size of support | Disk shape having diameter of | Disk shape having diameter of | Disk shape having diameter of | Disk shape having diameter of | Disk shape having diameter of |
| | | 200 mm | 200 mm | 200 mm | 200 mm | 200 mm |
| | Thickness of support | 0.775 mm | 0.775 mm | 0.775 mm | 0.775 mm | 0.775 mm |
| | Second adhesive | REVALPHA (manufactured | REVALPHA (manufactured | REVALPHA (manufactured | REVALPHA (manufactured | REVALPHA (manufactured |
| | | by Nitto Denko Corporation) | by Nitto Denko Corporation) | by Nitto Denko Corporation) | by Nitto Denko Corporation) | by Nitto Denko Corporation) |
| | Adhesive layer | Heating: 120° C./1 min | Heating: 120° C./1 min | Heating: 120° C./1 min | Heating: 120° C./1 min | Heating: 120° C./1 min |
| | degeneration | | | | | |
| | condition | | | | | |
| | Adhesive strength | 3 N/20 mm | 3 N/20 mm | 3 N/20 mm | 3 N/20 mm | 3 N/20 mm |
| | before degeneration | | | | | |
| | Adhesive strength | Equal to or smaller than | Equal to or smaller than | Equal to or smaller than | Equal to or smaller than | Equal to or smaller than |
| | after degeneration | 0.1 N/20 mm | 0.1 N/20 mm | 0.1 N/20 mm | 0.1 N/20 mm | 0.1 N/20 mm |
| Others | Frame | Not used | Stainless steel plate having | Stainless steel plate having | Not used | Not used |
| | | | thickness of 1 mm | thickness of 1 mm | | |
| | Intermediate | Not used | Not used | SPV-200 (manufactured by | Porous material with vacuum | Not used |
| | temporary adhesive | | | Nitto Denko Corporation) | pump | |
| | target 1 | | | | | |
| | Adhesive layer | — | — | None | — | — |
| | degeneration | | | | | |
| | condition | | | | | |
| | Adhesive strength | — | — | 0.8 N/20 mm | — | — |
| | before degeneration | | | | | |
| | Adhesive strength | — | — | 0.8 N/20 mm | — | — |
| | after degeneration | | | | | |
| | Intermediate | Not used | Not used | REVALPHA (manufactured | Porous material with vacuum | Not used |
| | temporary adhesive | | | by Nitto Denko Corporation) | pump | |
| | target 2 | | | | | |
| | Adhesive layer | — | — | Heating: 120° C./1 min | — | — |
| | degeneration | | | | | |
| | condition | | | | | |
| | Adhesive strength | — | — | 3 N/20 mm | — | — |
| | before degeneration | | | | | |
| | Adhesive strength | — | — | Equal to or smaller than | — | — |
| | after degeneration | | | 0.1 N/20 mm | | |
| Evaluation | Generation of defects | A | A | A | A | B |
| result | Conductivity | A | A | A | A | A |

TABLE 2

| | | Example 6 | Example 7 | Example 8 | Example 9 | Example 10 |
|---|---|---|---|---|---|---|
| Member to be treated | Metal oxide type | Aluminum oxide | Aluminum oxide | Aluminum oxide | Aluminum oxide | Aluminum oxide |
| | Thickness before | 0.1 mm | 0.1 mm | 0.1 mm | 0.1 mm | 0.1 mm |
| | treatment | | | | | |
| | Size of member to be | Disk shape having diameter | Disk shape having diameter | Disk shape having diameter | Disk shape having diameter | Disk shape having diameter |
| | treated | of 200 mm | of 200 mm | of 200 mm | of 200 mm | of 200 mm |
| | Hole diameter of | 70 nm | 70 nm | 70 nm | 70 nm | 70 nm |
| | micropores | | | | | |
| | Density of micropores | 10000000 pieces/mm² | 10000000 pieces/mm² | 10000000 pieces/mm² | 10000000 pieces/mm² | 10000000 pieces/mm² |
| | Conductor type | Copper | Copper | Copper | None | ITO |
| | Treatment means (first | Chemical mechanical | Chemical mechanical | Chemical mechanical | Chemical mechanical | Chemical mechanical |
| | surface) | polishing | polishing | polishing | polishing | polishing |
| | Treatment means | Chemical mechanical | Chemical mechanical | Chemical mechanical | Chemical mechanical | Chemical mechanical |
| | (second surface) | polishing | polishing | polishing | polishing | polishing |
| | Thickness after | 40 μm | 40 μm | 40 μm | 40 μm | 40 μm |
| | treatment of both | | | | | |
| | surfaces | | | | | |
| | Arithmetic average | 0.1 μm | 0.1 μm | 0.1 μm | 0.1 μm | 0.1 μm |
| | roughness after | | | | | |
| | treatment of both | | | | | |
| | surfaces (first surface) | | | | | |
| | Arithmetic average | 0.1 μm | 0.1 μm | 0.1 μm | 0.1 μm | 0.1 μm |
| | roughness after | | | | | |
| | treatment of both | | | | | |
| | surfaces (second | | | | | |
| | surface) | | | | | |
| Treatment | Treatment aspect | Manufacturing method 1 | Manufacturing method 1 | Manufacturing method 1 | Manufacturing method 1 | Manufacturing method 1 |
| method | | | | | | |
| First support | Material of support | Quartz glass | Quartz glass | Quartz glass | Quartz glass | Quartz glass |
| | Size of support | Disk shape having diameter | Disk shape having diameter | Disk shape having diameter | Disk shape having diameter | Disk shape having diameter |
| | | of 200 mm | of 200 mm | of 200 mm | of 200 mm | of 200 mm |
| | Thickness of support | 1 mm | 1 mm | 1 mm | 1 mm | 1 mm |
| | First adhesive | SOMATAC PS-1151CR | SELFA (manufactured by | SELFA (manufactured by | SELFA (manufactured by | SELFA (manufactured by |
| | | (manufactured by SOMAR | SEKISUI CHEMICAL | SEKISUI CHEMICAL | SEKISUI CHEMICAL | SEKISUI CHEMICAL |
| | | CORPORATION) | CO., LTD) | CO., LTD) | CO., LTD) | CO., LTD) |
| | Adhesive layer | Cooling (60° C. → 20° C.) | UV irradiation: 3000 mJ/cm² | UV irradiation: 3000 mJ/cm² | UV irradiation: 3000 mJ/cm² | UV irradiation: 3000 mJ/cm² |
| | degeneration condition | | | | | |
| | Adhesive strength | 1.6 N/20 mm | 10 N/20 mm | 10 N/20 mm | 10 N/20 mm | 10 N/20 mm |
| | before degeneration | | | | | |
| | Adhesive strength after | 0.1 N/20 mm | Equal to or smaller than | Equal to or smaller than | Equal to or smaller than | Equal to or smaller than |
| | degeneration | | 0.1 N/20 mm | 0.1 N/20 mm | 0.1 N/20 mm | 0.1 N/20 mm |
| Second | Material of support | Silicon | Silicon | Silicon | Silicon | Silicon |
| support | Size of support | Disk shape having diameter | Disk shape having diameter | Disk shape having diameter | Disk shape having diameter | Disk shape having diameter |
| | | of 200 mm | of 200 mm | of 200 mm | of 200 mm | of 200 mm |
| | Thickness of support | 0.775 mm | 0.775 mm | 0.775 mm | 0.775 mm | 0.775 mm |
| | Second adhesive | REVALPHA (manufactured | SRL0759 (double-sided | SOMATAC PS-1151CR | REVALPHA (manufactured | REVALPHA (manufactured |
| | | by Nitto Denko Corporation) | slightly pressure sensitive | (manufactured by SOMAR | by Nitto Denko Corporation) | by Nitto Denko Corporation) |
| | | | adhesive sheet manufactured | CORPORATION) | | |
| | | | by LINTEC Corporation) | | | |
| | Adhesive layer | Heating: 120° C./1 min | None | Cooling (60° C. → 20° C.) | Heating: 120° C./1 min | Heating: 120° C./1 min |
| | degeneration condition | | | | | |
| | Adhesive strength | 3 N/20 mm | 0.7 N/20 mm | 1.6 N/20 mm | 3 N/20 mm | 3 N/20 mm |
| | before degeneration | | | | | |
| | Adhesive strength after | Equal to or smaller than | Not changed | 0.1 N/20 mm | Equal to or smaller than | Equal to or smaller than |
| | degeneration | 0.1 N/20 mm | | | 0.1 N/20 mm | 0.1 N/20 mm |
| Others | Frame | Not used | Not used | Not used | Not used | Not used |
| | Intermediate temporary | Not used | Not used | Not used | Not used | Not used |
| | adhesive target 1 | | | | | |
| | Adhesive layer | — | — | — | — | — |
| | degeneration condition | | | | | |
| | Adhesive strength | — | — | — | — | — |
| | before degeneration | | | | | |
| | Adhesive strength after | — | — | — | — | — |
| | degeneration | | | | | |
| | Intermediate temporary | Not used | Not used | Not used | Not used | Not used |
| | adhesive target 2 | | | | | |
| | Adhesive layer | — | — | — | — | — |
| | degeneration condition | | | | | |
| | Adhesive strength | — | — | — | — | — |
| | before degeneration | | | | | |
| | Adhesive strength after | — | — | — | — | — |
| | degeneration | | | | | |
| Evaluation | Generation of defects | B | C | B | B | B |
| result | Conductivity | A | A | A | D | B |

TABLE 3

| | | Example 11 | Example 12 | Example 13 | Example 14 | Example 15 |
|---|---|---|---|---|---|---|
| Member to be treated | Metal oxide type | Aluminum oxide | Aluminum oxide | Aluminum oxide | Aluminum oxide | Aluminum oxide |
| | Thickness before | 0.1 mm | 0.1 mm | 0.1 mm | 0.1 mm | 0.1 mm |
| | treatment | | | | | |
| | Size of member to be | Disk shape having diameter | Disk shape having diameter of | Disk shape having diameter of | Disk shape having diameter | Disk shape having diameter |
| | treated | of 200 mm | 200 mm | 200 mm | of 200 mm | of 200 mm |
| | Hole diameter of | 70 nm | 70 nm | 70 nm | 70 nm | 70 nm |
| | micropores | | | | | |
| | Density of micropores | 10000000 pieces/mm² | 10000000 pieces/mm² | 10000000 pieces/mm² | 10000000 pieces/mm² | 10000000 pieces/mm² |
| | Conductor type | Aluminum | Magnesium | Copper | Copper | Copper |
| | Treatment means (first | Chemical mechanical | Chemical mechanical | Chemical mechanical | Chemical mechanical | Chemical mechanical |
| | surface) | polishing | polishing | polishing | polishing | polishing |
| | Treatment means | Chemical mechanical | Chemical mechanical | Chemical mechanical | Chemical mechanical | Chemical mechanical |
| | (second surface) | polishing | polishing | polishing | polishing | polishing |
| | Thickness after | 40 μm | 40 μm | 40 μm | 40 μm | 80 μm |
| | treatment of both | | | | | |
| | surfaces | | | | | |
| | Arithmetic average | 0.1 μm | 0.1 μm | 0.5 μm | 0.1 μm | 0.1 μm |
| | roughness after | | | | | |
| | treatment of both | | | | | |
| | surfaces (first surface) | | | | | |
| | Arithmetic average | 0.1 μm | 0.1 μm | 0.5 μm | 0.1 μm | 0.1 μm |
| | roughness after | | | | | |
| | treatment of both | | | | | |
| | surfaces (second | | | | | |
| | surface) | | | | | |
| Treatment | Treatment aspect | Manufacturing method 1 | Manufacturing method 1 | Manufacturing method 1 | Manufacturing method 1 | Manufacturing method 1 |
| method | | | | | | |
| First support | Material of support | Quartz glass | Quartz glass | Quartz glass | Silicon | Quartz glass |
| | Size of support | Disk shape having diameter | Disk shape having diameter of | Disk shape having diameter of | Disk shape having diameter | Disk shape having diameter |
| | | of 200 mm | 200 mm | 200 mm | of 200 mm | of 200 mm |
| | Thickness of support | 1 mm | 1 mm | 1 mm | 0.775 mm | 1 mm |
| | First adhesive | SELFA (manufactured by | SELFA (manufactured by | SELFA (manufactured by | REVALPHA (manufactured | SELFA (manufactured by |
| | | SEKISUI CHEMICAL | SEKISUI CHEMICAL | SEKISUI CHEMICAL | by Nitto Denko Corporation) | SEKISUI CHEMICAL |
| | | CO., LTD) | CO., LTD) | CO., LTD) | | CO., LTD) |
| | Adhesive layer | UV irradiation: 3000 mJ/cm² | UV irradiation: 3000 mJ/cm² | UV irradiation: 3000 mJ/cm² | Heating: 120° C./1 min | UV irradiation: 3000 mJ/cm² |
| | degeneration condition | | | | | |
| | Adhesive strength | 10 N/20 mm | 10 N/20 mm | 10 N/20 mm | 3 N/20 mm | 10 N/20 mm |
| | before degeneration | | | | | |
| | Adhesive strength after | Equal to or smaller than | Equal to or smaller than | Equal to or smaller than | Equal to or smaller than | Equal to or smaller than |
| | degeneration | 0.1 N/20 mm | 0.1 N/20 mm | 0.1 N/20 mm | 0.1 N/20 mm | 0.1 N/20 mm |
| Second | Material of support | Silicon | Silicon | Silicon | Quartz glass | Silicon |
| support | Size of support | Disk shape having diameter | Disk shape having diameter of | Disk shape having diameter of | Disk shape having diameter | Disk shape having diameter |
| | | of 200 mm | 200 mm | 200 mm | of 200 mm | of 200 mm |
| | Thickness of support | 0.775 mm | 0.775 mm | 0.775 mm | 1 mm | 0.775 mm |
| | Second adhesive | REVALPHA (manufactured | REVALPHA (manufactured | REVALPHA (manufactured | SELFA (manufactured by | REVALPHA (manufactured |
| | | by Nitto Denko | by Nitto Denko Corporation) | by Nitto Denko Corporation) | SEKISUI CHEMICAL | by Nitto Denko Corporation) |
| | | Corporation) | | | CO., LTD) | |
| | Adhesive layer | Heating: 120° C./1 min | Heating: 120° C./1 min | Heating: 120° C./1 min | UV irradiation: 3000 mJ/cm² | Heating: 120° C./1 min |
| | degeneration condition | | | | | |
| | Adhesive strength | 3 N/20 mm | 3 N/20 mm | 3 N/20 mm | 10 N/20 mm | 3 N/20 mm |
| | before degeneration | | | | | |
| | Adhesive strength after | Equal to or smaller than | Equal to or smaller than | Equal to or smaller than | Equal to or smaller than | Equal to or smaller than |
| | degeneration | 0.1 N/20 mm | 0.1 N/20 mm | 0.1 N/20 mm | 0.1 N/20 mm | 0.1 N/20 mm |
| Others | Frame | Not used | Not used | Not used | Not used | Not used |
| | Intermediate temporary | Not used | Not used | Not used | Not used | Not used |
| | adhesive target 1 | | | | | |
| | Adhesive layer | — | — | — | — | — |
| | degeneration condition | | | | | |
| | Adhesive strength | — | — | — | — | — |
| | before degeneration | | | | | |
| | Adhesive strength after | — | — | — | — | — |
| | degeneration | | | | | |
| | Intermediate temporary | Not used | Not used | Not used | Not used | Not used |
| | adhesive target 2 | | | | | |
| | Adhesive layer | — | — | — | — | — |
| | degeneration condition | | | | | |
| | Adhesive strength | — | — | — | — | — |
| | before degeneration | | | | | |
| | Adhesive strength after | — | — | — | — | — |
| | degeneration | | | | | |
| Evaluation | Generation of defects | B | B | A | A | A |
| result | Conductivity | B | B | B | A | A |

TABLE 4

| | | Example 16 | Example 17 | Example 18 | Example 19 | Example 20 | Comparative Example 1 |
|---|---|---|---|---|---|---|---|
| Member to | Metal oxide type | Aluminum oxide | Aluminum oxide | Aluminum oxide | Aluminum oxide | Aluminum oxide | Aluminum oxide |
| be treated | Thickness before | 0.1 mm | 0.1 mm | 0.1 mm | 0.1 mm | 0.1 mm | 0.1 mm |
| | treatment | | | | | | |
| | Size of member to | Disk shape having | Disk shape having | Disk shape having | Disk shape having | Disk shape having | Disk shape having |
| | be treated | diameter of 200 mm | diameter of 200 mm | diameter of 200 mm | diameter of 200 mm | diameter of 200 mm | diameter of 200 mm |
| | Hole diameter of | 70 nm | 70 nm | 100 nm | 70 nm | 70 nm | 70 nm |
| | micropores | | | | | | |
| | Density of | 10000000 pieces/mm² | 10000000 pieces/mm² | 10000000 pieces/mm² | 10000000 pieces/mm² | 10000000 pieces/mm² | 10000000 pieces/mm² |
| | micropores | | | | | | |
| | Conductor type | Copper | Copper | Copper | Copper | Copper | Copper |
| | Treatment means | Chemical mechanical | Chemical mechanical | Chemical mechanical | Chemical mechanical | Chemical mechanical | Chemical mechanical |
| | (first surface) | polishing | polishing | polishing | polishing | polishing | polishing |
| | Treatment means | Chemical mechanical | Chemical mechanical | Chemical mechanical | Chemical mechanical | Chemical mechanical | Chemical mechanical |
| | (second surface) | polishing | polishing | polishing | polishing | polishing | polishing |
| | Thickness after | 40 μm | 40 μm | 40 μm | 40 μm | 40 μm | 40 μm |
| | treatment of both | | | | | | |
| | surfaces | | | | | | |
| | Arithmetic average | 0.1 μm | 0.1 μm | 0.1 μm | Equal to or greater than | 0.1 μm | 0.1 μm |
| | roughness after | | | | 1 μm | | |
| | treatment of both | | | | | | |
| | surfaces (first | | | | | | |
| | surface) | | | | | | |
| | Arithmetic average | 0.1 μm | 0.1 μm | 0.1 μm | Equal to or greater than | 0.1 μm | 0.1 μm |
| | roughness after | | | | 1 μm | | |
| | treatment of both | | | | | | |
| | surfaces (second | | | | | | |
| | surface) | | | | | | |
| Treatment | Treatment aspect | Manufacturing method 1 | Manufacturing method 1 | Manufacturing method 1 | Manufacturing method 1 | Manufacturing method 1 | Method of related art |
| method | | | | | | | |
| First support | Material of support | Quartz glass | Quartz glass | Quartz glass | Quartz glass | Quartz glass | Quartz glass |
| | Size of support | Disk shape having | Disk shape having | Disk shape having | Disk shape having | Disk shape having | Disk shape having |
| | | diameter of 200 mm | diameter of 200 mm | diameter of 200 mm | diameter of 200 mm | diameter of 200 mm | diameter of 200 mm |
| | Thickness of support | 1 mm | 1 mm | 1 mm | 1 mm | 2 mm | 1 mm |
| | First adhesive | SELFA (manufactured by | SELFA (manufactured by | SELFA (manufactured by | SELFA (manufactured by | SELFA (manufactured by | SELFA (manufactured by |
| | | SEKISUI CHEMICAL | SEKISUI CHEMICAL | SEKISUI CHEMICAL | SEKISUI CHEMICAL | SEKISUI CHEMICAL | SEKISUI CHEMICAL |
| | | CO., LTD) | CO., LTD) | CO., LTD) | CO., LTD) | CO., LTD) | CO., LTD) |
| | Adhesive layer | Laser irradiation: | UV irradiation: | UV irradiation: | UV irradiation: | UV irradiation: | UV irradiation: |
| | degeneration | wavelength of 380 nm, | 3000 mJ/cm² | 3000 mJ/cm² | 3000 mJ/cm² | 3000 mJ/cm² | 3000 mJ/cm² |
| | condition | output of 5 W | | | | | |
| | Adhesive strength | 10 N/20 mm | 10 N/20 mm | 10 N/20 mm | 10 N/20 mm | 10 N/20 mm | 10 N/20 mm |
| | before degeneration | | | | | | |
| | Adhesive strength | Equal to or smaller than | Equal to or smaller than | Equal to or smaller than | Equal to or smaller than | Equal to or smaller than | Equal to or smaller than |
| | after degeneration | 0.1 N/20 mm | 0.1 N/20 mm | 0.1 N/20 mm | 0.1 N/20 mm | 0.1 N/20 mm | 0.1 N/20 mm |
| Second | Material of support | Silicon | Quartz glass | Silicon | Silicon | Silicon | Silicon |
| support | Size of support | Disk shape having | Disk shape having | Disk shape having | Disk shape having | Disk shape having | Disk shape having |
| | | diameter of 200 mm | diameter of 200 mm | diameter of 200 mm | diameter of 200 mm | diameter of 200 mm | diameter of 200 mm |
| | Thickness of support | 0.775 mm | 1 mm | 0.775 mm | 0.775 mm | 1.5 mm | 0.775 mm |
| | Second adhesive | REVALPHA | SELFA (manufactured by | REVALPHA | REVALPHA | REVALPHA | REVALPHA |
| | | (manufactured by Nitto | SEKISUI CHEMICAL | (manufactured by Nitto | (manufactured by Nitto | (manufactured by Nitto | (manufactured by Nitto |
| | | Denko Corporation) | CO., LTD) | Denko Corporation) | Denko Corporation) | Denko Corporation) | Denko Corporation) |
| | Adhesive layer | Heating: 120° C./1 min | UV irradiation: | Heating: 120° C./1 min | Heating: 120° C./1 min | Heating: 120° C./1 min | Heating: 120° C./1 min |
| | degeneration | | 3000 mJ/cm² | | | | |
| | condition | | | | | | |
| | Adhesive strength | 3 N/20 mm | 10 N/20 mm | 3 N/20 mm | 3 N/20 mm | 3 N/20 mm | 3 N/20 mm |
| | before degeneration | | | | | | |
| | Adhesive strength | Equal to or smaller than | Equal to or smaller than | Equal to or smaller than | Equal to or smaller than | Equal to or smaller than | Equal to or smaller than |
| | after degeneration | 0.1 N/20 mm | 0.1 N/20 mm | 0.1 N/20 mm | 0.1 N/20 mm | 0.1 N/20 mm | 0.1 N/20 mm |
| Others | Frame | Not used | Not used | Not used | Not used | Not used | Not used |
| | Intermediate | Not used | Not used | Not used | Not used | Not used | Not used |
| | temporary adhesive | | | | | | |
| | target 1 | | | | | | |
| | Adhesive layer | — | — | — | — | — | — |
| | degeneration | | | | | | |
| | condition | | | | | | |
| | Adhesive strength | — | — | — | — | — | — |
| | before degeneration | | | | | | |
| | Adhesive strength | — | — | — | — | — | — |
| | after degeneration | | | | | | |
| | Intermediate | Not used | Not used | Not used | Not used | Not used | Not used |
| | temporary adhesive | | | | | | |
| | target 2 | | | | | | |
| | Adhesive layer | — | — | — | — | — | — |
| | degeneration | | | | | | |
| | condition | | | | | | |
| | Adhesive strength | — | — | — | — | — | — |
| | before degeneration | | | | | | |
| | Adhesive strength | — | — | — | — | — | — |
| | after degeneration | | | | | | |
| Evaluation | Generation of | A | A | A | A | A | D |
| result | defects | | | | | | |
| | Conductivity | A | A | A | B | A | C |

As shown in Tables 1 to 4, in Examples 1 to 20, the number of generated defects having a size equal to or greater than 30 μm was small, compared to Comparative Example 1. In Examples 1 to 8 and Examples 10 to 20, except Example 9 not including the conductor, more excellent result regarding the conductivity was obtained, compared to Comparative Example 1.

In Examples 5 and 6, the first adhesive is different from that in Example 1, and the number of defects was slightly great, compared to Example 1.

In Examples 7 and 8, the second adhesive is different from that in Example 1, and the number of defects was great, compared to Example 1.

Example 9 is different from Example 1, in that the conductor is not included, the number of defects was slightly great and conductivity was deteriorated, compared to Example 1.

In Examples 10 to 12, the conductor type is different from that in Example 1, the number of defects was slightly great and conductivity was slightly deteriorated, compared to Example 1.

In Examples 13 and 19, the arithmetic average roughness is rough that in Example 1, and conductivity was slightly deteriorated, compared to Example 1.

The invention is basically configured as described above. Hereinafter, the method for manufacturing a member to be treated and the laminate of the invention have been described in detail, but the invention is not limited to the embodiments described above, and various modifications and changes may be performed with in a range not departing from the gist of the invention.

### EXPLANATION OF REFERENCES

10, 100: first support
10a, 12a, 16a, 40a, 104a: surface
12: first adhesive layer
14, 104: substrate
14a: first surface
14b: second surface
15: anisotropic conductive member
16, 106: second support
17: laminate
18: second adhesive layer
20, 21: temporary support
22: frame
22a: opening
24: adhesive sheet
25: cutter
26: adhesive sheet
28: anisotropic conductive material
30: first transfer support
32: second transfer support
40: insulating base material
40b, 104b: rear surface
41: penetration path
42: conductive path
42a, 42b: protrusion portion
43: base portion
44: resin layer
46: support base body
47: peeling layer
48: support layer
49: release agent
50: portion
102: first temporary bonding layer
108: second temporary bonding layer
Dt: distance
Z: thickness direction
h: thickness
p: distance between centers
x: direction

What is claimed is:

1. A method for manufacturing a member to be treated comprising:
a first bonding step of bonding a member to be treated containing metal oxide and a first support to each other with a first adhesive layer;
a first surface processing step of processing the member to be treated to form a first processed surface;
a first surface contact step of bringing one of a support having adhesiveness, an adsorption support which adsorbs the member to be treated, and a second adhesive layer, into contact with the first processed surface;
a second bonding step of bonding the member to be treated and a second support with the second adhesive layer which is in contact with the first processed surface; and
a second surface processing step of processing the member to be treated to form a second processed surface on a rear surface of the first processed surface, in this order,
wherein a step of removing the support having adhesiveness or the adsorption support is included in the first surface contact step, in a case where the support having adhesiveness or the adsorption support and the first processed surface are in contact with each other, and
a first adhesive layer removing step of removing the first adhesive layer from the member to be treated is included between the first surface contact step and the second bonding step or between the second bonding step and the second surface processing step.

2. The method for manufacturing a member to be treated according to claim 1, further comprising:
a first adhesive layer degeneration step of decreasing adhesive strength of the first adhesive layer between the first surface processing step and the first adhesive layer removing step.

3. The method for manufacturing a member to be treated according to claim 2,
wherein the first adhesive layer degeneration step includes at least one of exposure or heating.

4. The method for manufacturing a member to be treated according to claim 1, further comprising:
a second adhesive layer degeneration step of decreasing adhesive strength of the second adhesive layer after the second surface processing step.

5. The method for manufacturing a member to be treated according to claim 4,
wherein the second adhesive layer degeneration step includes at least one of exposure or heating.

6. The method for manufacturing a member to be treated according to claim 1,
wherein the first adhesive layer removing step is included between the second bonding step and the second surface processing step.

7. The method for manufacturing a member to be treated according to claim 1,
wherein the second bonding step is a step of sticking the second support to the second adhesive layer provided on the first processed surface of the member to be treated.

8. The method for manufacturing a member to be treated according to claim 1,
wherein the first bonding step is a step of sticking the member to be treated to the first adhesive layer provided on the first support.

9. The method for manufacturing a member to be treated according to claim 1,
wherein the member to be treated includes a conductor.

10. The method for manufacturing a member to be treated according to claim 9,
wherein the conductor includes unoxidized metal.

11. The method for manufacturing a member to be treated according to claim 1,
wherein the metal oxide is oxide of base metal.

12. The method for manufacturing a member to be treated according to claim 1,
wherein both of the first processed surface and the second processed surface are surfaces having an arithmetic average roughness equal to or smaller than 1 μm.

13. The method for manufacturing a member to be treated according to claim 1,
wherein the second surface processing step is a step of processing a surface having been in contact with the first adhesive layer, among surfaces of the member to be treated.

14. The method for manufacturing a member to be treated according to claim 1,
wherein adhesive strength of the first adhesive layer is always smaller than adhesive strength of the second adhesive layer.

15. The method for manufacturing a member to be treated according to claim 1,
wherein at least one of the first support or the second support has at least one transmission region, and a transmittance of the transmission region is 70% or more in a wavelength range of 200 to 500 nm.

16. The method for manufacturing a member to be treated according to claim 1,
wherein a distance between the first processed surface and the second processed surface of the member to be treated is equal to or smaller than 50 μm.

17. The method for manufacturing a member to be treated according to claim 3,
wherein the exposure is laser irradiation or ultraviolet irradiation.

18. The method for manufacturing a member to be treated according to claim 5,
wherein the exposure is laser irradiation or ultraviolet irradiation.

19. The method for manufacturing a member to be treated according to claim 1,
wherein at least one of the first adhesive layer or the second adhesive layer includes a material which decreases adhesiveness of the adhesive layer by heating.

20. A laminate used in the method for manufacturing a member to be treated according to claim 1, the laminate comprising:
the first support;
the first adhesive layer; and
the member to be treated, in this order.
